(19) United States
(12) Patent Application Publication
(10) Pub. No.: US 2017/0162812 A1
(43) Pub. Date: Jun. 8, 2017

(54) ORGANIC THIN FILM PHOTOVOLTAIC DEVICE AND ELECTRONIC APPARATUS

(71) Applicant: ROHM CO., LTD., Kyoto (JP)

(72) Inventor: Yoichi AOKI, Kyoto (JP)

(21) Appl. No.: 15/442,354

(22) Filed: Feb. 24, 2017

Related U.S. Application Data
(63) Continuation of application No. PCT/JP2015/061328, filed on Apr. 13, 2015.

(30) Foreign Application Priority Data
Aug. 29, 2014 (JP) 2014-176182

(51) Int. Cl. H01L 51/44; H01L 51/42

(52) U.S. Cl. CPC H01L 51/448; H01L 51/441; H01L 51/4253

(57) ABSTRACT

An organic thin film photovoltaic device and an electronic apparatus in which the organic thin film photovoltaic device is mounted, wherein the organic thin film photovoltaic device includes: a substrate; a transparent electrode layer disposed on the substrate; an organic layer disposed on the transparent electrode layer; a metal electrode layer disposed on the organic layer; a passivation layer disposed on the metal electrode layer; a photo-curing resin layer disposed on the passivation layer; and a barrier film disposed on a photo-curing resin layer. There are provided: the organic thin film photovoltaic device, of which a fabrication process is simplified and durability is excellent; and the electronic apparatus in which the organic thin film photovoltaic device is mounted.

### CROSS REFERENCE TO RELATED APPLICATIONS

This is a continuation application (CA) of PCT Application No. PCT/JP2015/061328, filed on Apr. 13, 2015, which claims priority to Japan Patent Application No. P2014-176182 filed on Aug. 29, 2014 and is based upon and claims the benefit of priority from prior Japanese Patent Application No. P2014-176182 filed on Aug. 29, 2014 and PCT Application No. PCT/JP2015/061328, filed on Apr. 13, 2015, the entire contents of each of which are incorporated herein by reference.

### FIELD

The embodiment described herein relates to an organic thin film photovoltaic device and an electronic apparatus.

### BACKGROUND

Since organic thin film photovoltaic devices characterized by ultra-thin structure, lightness in weight, and flexibility are fabricated using printing methods, e.g. an ink-jet process, under room temperature and atmospheric pressure, well-designed solar cells having high flexibility of shape can be realized.

### SUMMARY

The embodiment provides: an organic thin film photovoltaic device, of which a fabrication process is simplified and durability is excellent, by bonding a barrier film excellent in a mechanical strength and a barrier property to a single-layered protection film with an ultraviolet (UV) curing resin; and an electronic apparatus in which such an organic thin film photovoltaic device is mounted.

According to one aspect of the embodiment, there is provided an organic thin film photovoltaic device comprising: a substrate; a transparent electrode layer disposed on the substrate; an organic layer disposed on the transparent electrode layer; a metal electrode layer disposed on the organic layer; a passivation layer disposed on the metal electrode layer; a photo-curing resin layer disposed on the passivation layer; and a barrier film disposed on the photo-curing resin layer.

According to another aspect of the embodiment, there is provided an organic thin film photovoltaic device comprising an organic thin film photovoltaic device cell, the organic thin film photovoltaic device cell comprising: a substrate; a first electrode layer disposed on the substrate; an organic layer disposed on the first electrode layer; a second electrode layer disposed on the organic layer; a passivation layer disposed on the second electrode layer; a photo-curing resin layer disposed on the passivation layer; and a barrier film disposed on the photo-curing resin layer, wherein a plurality of the organic thin film photovoltaic device cells are connected to one another in series.

According to still another aspect of the embodiment, there is provided an electronic apparatus comprising the above-mentioned organic thin film photovoltaic device.

According to the embodiment, there can be provided: the organic thin film photovoltaic device, of which the fabrication process is simplified and durability is excellent, by bonding the barrier film excellent in the mechanical strength and the barrier property to the single-layered protection film with the UV curing resin; and the electronic apparatus in which such an organic thin film photovoltaic device is mounted.

### BRIEF DESCRIPTION OF DRAWINGS

FIG. 1A is a schematic cross-sectional structure diagram showing an organic thin film photovoltaic device and an organic thin film photovoltaic device cell, according to a comparative example using a cell sealing with a multi-layered protection film.

FIG. 1B is a schematic cross-sectional structure diagram showing a state where a foreign substance is added into the multi-layered protection film shown in FIG. 1A.

FIG. 2 shows time change characteristics of an electric-generating capacity in a thermal resistance and moisture resistance test, in the organic thin film photovoltaic device according to the comparative example.

FIG. 3A is a schematic planar pattern configuration diagram at a side of a light-receiving surface, in a process of a fabrication method of the organic thin film photovoltaic device according to the comparative example.

FIG. 3B is a process chart of pattern-forming a transparent electrode layer on a substrate, corresponding to a schematic cross-sectional structure of a portion taken in the line I-I of FIG. 3A.

FIG. 3C is a process chart of pattern-forming an organic layer on the transparent electrode layer, corresponding to the schematic cross-sectional structure of the portion taken in the line I-I of FIG. 3A.

FIG. 4A is a process chart of pattern-forming a second electrode layer on the organic layer, corresponding to the schematic cross-sectional structure of the portion taken in the line I-I of FIG. 3A, in a process of the fabrication method of the organic thin film photovoltaic device according to the comparative example.

FIG. 4B is a process chart of forming a passivation layer composed including a multi-layered protection film on the entire surface of device, in a process of the fabrication method of the organic thin film photovoltaic device according to the comparative example.

FIG. 5 is a schematic cross-sectional structure diagram of an organic thin film photovoltaic device and an organic thin film photovoltaic device cell, according to the embodiment.

FIG. 6 is a schematic diagram for explaining theoretic configuration and operation of the organic thin film photovoltaic device according to the embodiment.

FIG. 7 is an energy band structure diagram showing various kinds of materials of the organic thin film photovoltaic device shown in FIG. 6.

FIG. 8A shows a chemical structural formula of PEDOT applied to the organic thin film photovoltaic device according to the embodiment.

FIG. 8B shows a chemical structural formula of PSS applied to the organic thin film photovoltaic device according to the embodiment.

FIG. 9A shows a chemical structural formula of P3HT used as a p type material applied to the organic thin film photovoltaic device according to the embodiment.

FIG. 9B shows a chemical structural formula of PCBM used as an n type material applied to the organic thin film photovoltaic device according to the embodiment.

FIG. 10 shows time change characteristics of an electric-generating capacity in a thermal resistance and moisture resistance test, in the organic thin film photovoltaic device according to the embodiment.

FIG. 11 shows time change characteristics of an electric-generating capacity in a light continuous irradiation test (AS: amorphous-silicon solar cell; OTF: organic thin film photovoltaic device), in the organic thin film photovoltaic device according to the embodiment.

FIG. 12A is a schematic planar pattern configuration diagram at a side of a terminal-extracting surface, in a process of a fabrication method of the organic thin film photovoltaic device according to the embodiment.

FIG. 12B is a process chart of pattern-forming a transparent electrode layer on a substrate, corresponding to a schematic cross-sectional structure of a portion taken in the line II-II of FIG. 12A.

FIG. 12C is a process chart of pattern-forming an organic layer on the transparent electrode layer, corresponding to the schematic cross-sectional structure of the portion taken in the line II-II of FIG. 12A.

FIG. 13A is a process chart of pattern-forming a second electrode layer on the organic layer, corresponding to the schematic cross-sectional structure of the portion taken in the line II-II of FIG. 12A, in a process of the fabrication method of the organic thin film photovoltaic device according to the embodiment.

FIG. 13B is a process chart of forming a passivation layer composed including a multi-layered protection film on the entire surface of the device, corresponding to the schematic cross-sectional structure of the portion taken in the line II-II of FIG. 12A, in a process of the fabrication method of the organic thin film photovoltaic device according to the embodiment.

FIG. 14 is a process chart of bonding a barrier film via a photo-curing resin layer on the passivation layer, corresponding to the schematic cross-sectional structure of the portion taken in the line II-II of FIG. 12A, in a process of the fabrication method of the organic thin film photovoltaic device according to the embodiment.

FIG. 15A is a schematic bird's-eye view showing an organic thin film photovoltaic device module having a 4-cells serial structure disposed on the substrate in a matrix shape, in a process of the fabrication method of the organic thin film photovoltaic device according to the embodiment.

FIG. 15B is a module dicing process chart, in a process of the fabrication method of the organic thin film photovoltaic device according to the embodiment.

FIG. 16 shows time change characteristics of an electric-generating capacity in a heat-resistant (high temperature preservation) test (AS: amorphous-silicon solar cell; OTF: organic thin film photovoltaic device), in the organic thin film photovoltaic device according to the embodiment.

FIG. 17A shows an example of a temperature profile applied to a thermal shock cycle test, in the organic thin film photovoltaic device according to the embodiment.

FIG. 17B shows an example of a temperature profile applied to a temperature cycle test, in the organic thin film photovoltaic device according to the embodiment.

FIG. 18A is a schematic planar pattern configuration diagram at a side of a terminal-extracting surface of the organic thin film photovoltaic device module having a 4-cells serial structure, in the organic thin film photovoltaic device according to the embodiment.

FIG. 18B shows equivalent circuit representation of the organic thin film photovoltaic device module having the 4-cells serial structure, in the organic thin film photovoltaic device according to the embodiment.

FIG. 19 is a schematic cross-sectional structure diagram taken in the line of FIG. 18A.

FIG. 20 is a schematic planar pattern configuration diagram at a side of a terminal-extracting surface of an organic thin film photovoltaic device module having a 4-cells serial structure, in an organic thin film photovoltaic device according to a modified example of the embodiment.

FIG. 21 is a schematic cross-sectional structure diagram taken in the line IV-IV of FIG. 20.

FIG. 22 shows time change characteristics of a normalized open voltage, in a result (relative values) of a moisture resistance test (environmental test) of the organic thin film photovoltaic device modules according to the embodiment and its modified example.

FIG. 23 shows time change characteristics of a normalized saturation current, in a result (relative values) of the moisture resistance test (environmental test) of the organic thin film photovoltaic device modules according to the embodiment and its modified example.

FIG. 24 shows time change characteristics of a normalized fill factor, in a result (relative values) of the moisture resistance test (environmental test) of the organic thin film photovoltaic device modules according to the embodiment and its modified example.

FIG. 25 shows time change characteristics of a normalized maximum electric-generating capacity, in a result (relative values) of the moisture resistance test (environmental test) of the organic thin film photovoltaic device modules according to the embodiment and its modified example.

FIG. 26 shows time change characteristics of an open voltage, in a result (absolute values) of a moisture resistance test (environmental test) of the organic thin film photovoltaic device modules according to the embodiment and its modified example.

FIG. 27 shows time change characteristics of a saturation current, in a result (absolute values) of a moisture resistance test (environmental test) of the organic thin film photovoltaic device modules according to the embodiment and its modified example.

FIG. 28 shows time change characteristics of a fill factor, in a result (absolute values) of the moisture resistance test (environmental test) of the organic thin film photovoltaic device modules according to the embodiment and its modified example.

FIG. 29 shows time change characteristics of a maximum electric-generating capacity, in a result (absolute values) of the moisture resistance test (environmental test) of the organic thin film photovoltaic device modules according to the embodiment and its modified example.

FIG. 30A is a plane configuration diagram for explaining an electrode connection relationship at a side of a terminal-extracting surface of an organic thin film photovoltaic device module having a 4-cells serial structure, in the organic thin film photovoltaic device according to the embodiment.

FIG. 30B shows equivalent circuit representation corresponding to FIG. 30A.

FIG. 31A is a schematic plane configuration diagram of a cathode electrode and an anode electrode at the side of a terminal-extracting surface of an organic thin film photovoltaic device module having a 4-cells serial structure, in the organic thin film photovoltaic device according to the embodiment.

FIG. 31B is a schematic cross-sectional structure diagram taken in the line V-V of FIG. 31A.

FIG. 31C is a schematic cross-sectional structure diagram taken in the line VI-VI of FIG. 31A.

FIG. 32A is a schematic diagram showing a conduction path of a photo-electric current, in the organic thin film photovoltaic device module having the 4-cells serial structure shown in FIG. 31A.

FIG. 32B is a diagram showing a conducting direction of the photo-electric current in equivalent circuit representation, in the organic thin film photovoltaic device module having the 4-cells serial structure shown in FIG. 31A.

FIG. 32C is a schematic diagram showing current-voltage characteristics, in the organic thin film photovoltaic device module having the 4-cells serial structure shown in FIG. 31A.

FIG. 33 is a flow chart showing producing steps of the organic thin film photovoltaic device according to the embodiment.

FIG. 34 is a schematic bird's-eye view structure diagram showing a state where a stripe pattern of the transparent electrode layers is formed on the substrate, in a process of the mass production fabricating process of the organic thin film photovoltaic device according to the embodiment.

FIG. 35 is a schematic bird's-eye view structure diagram showing a state where the hole transport layer is formed as a film with spin coating on the stripe-shaped transparent electrode layer, in a process of the mass production fabricating process of the organic thin film photovoltaic device according to the embodiment.

FIG. 36 is a schematic bird's-eye view structure diagram showing a state where the bulk heterojunction organic active layer is formed as a film with spin coating on the hole transport layer, in a process of a mass production fabricating process of the organic thin film photovoltaic device according to the embodiment.

FIG. 37 is a schematic bird's-eye view configuration diagram showing a state where a stripe pattern of the second electrode layer formed so as to be intersected perpendicularly with the stripe-shaped transparent electrode layer on the bulk heterojunction organic active layer, in a process of the mass production fabricating process of the organic thin film photovoltaic device according to the embodiment.

FIG. 38 is a schematic planar pattern configuration diagram showing an example which disposes a plurality of cells Cij in a matrix shape, in the organic thin film photovoltaic device according to the embodiment.

FIG. 39A is a schematic diagram showing a spin coat method at the time of forming the hole transport layer and the bulk heterojunction organic active layer, in the fabrication method of the organic thin film photovoltaic device according to the embodiment.

FIG. 39B is a schematic bird's-eye view configuration diagram showing an example of the hole transport layer and the bulk heterojunction organic active layer formed in the fabrication method of the organic thin film photovoltaic device according to the embodiment.

### DESCRIPTION OF EMBODIMENTS

Next, the embodiment will be described with reference to drawings. In the description of the following drawings, the identical or similar reference numeral is attached to the identical or similar part. However, it should be noted that the drawings are schematic and therefore the relation between thickness and the plane size and the ratio of the thickness differs from an actual thing. Therefore, detailed thickness and size should be determined in consideration of the following explanation. Of course, the part from which the relation and ratio of a mutual size differ also in mutually drawings is included.

Moreover, the embodiment shown hereinafter exemplifies the apparatus and method for materializing the technical idea; and the embodiment does not specify the material, shape, structure, placement, etc. of each component part as the following. The embodiment may be changed without departing from the spirit or scope of claims.

In an organic thin film photovoltaic device according to the following embodiment, “transparent” is defined as that whose transmissivity is not less than approximately 50%. In the organic thin film photovoltaic device according to the embodiment, the “transparent” is used for the purpose of being transparent and colorless with respect to visible light. The visible light is equivalent to light having a wavelength of approximately 360 nm to approximately 830 nm and energy of approximately 3.45 eV to approximately 1.49 eV, and it can be said that it is transparent if the transmission rate is not less than 50% in such a region.

### Comparative Example

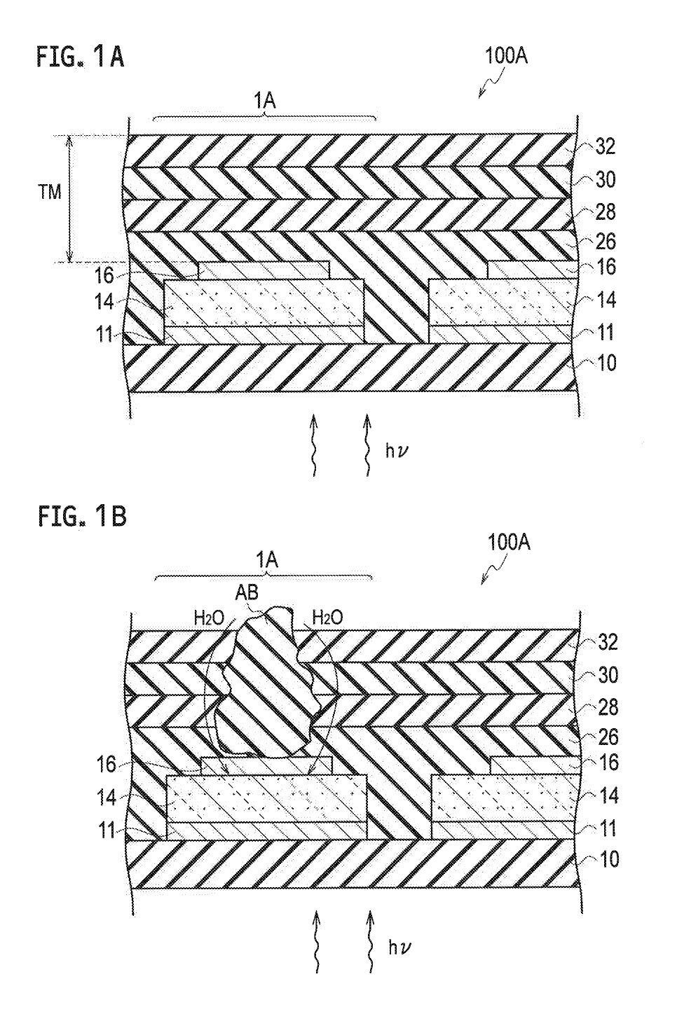

FIG. 1A shows a schematic cross-sectional structure of an organic thin film photovoltaic device 100A and an organic thin film photovoltaic device cell 1A, according to a comparative example using a cell sealing with a multi-laminated protection film. FIG. 1B shows a schematic cross-sectional structure in a state where a foreign substance AB is added into a multi-laminated protection film shown in FIG. 1A.

As shown in FIG. 1A, the organic thin film photovoltaic device 100A according to the comparative example includes: a substrate 10; an optically transmissive electrode layer 11 disposed on the substrate 10; an organic layer 14 disposed on the transparent electrode layer 11; a metal electrode layer 16 disposed on the organic layer 14; and passivation layers 26, 28, 30, 32 disposed on the metal electrode layer 16.

In the present embodiment, the passivation layers 26, 28, 30, 32 compose a multi-laminated protection film. The passivation layers 26, 30 include an inorganic protection film composed including an SiN film or an SiON film, and the passivation layers 28, 32 include an organic protective film composed including a resin layer, etc. A thickness TM of the multi-laminated protection film shown in FIG. 1A is approximately 10 μm, for example.

In the organic thin film photovoltaic device cell 1A according to the comparative example using the cell sealing with the multi-laminated protection film, a module thereof is relatively thin and slight, but a forming process of the multi-laminated protection film is relatively long, of which a time required for a total of 4 processes is approximately 2 hours. Since the thickness TM of the multi-laminated protection film is relatively thin, the multi-laminated protection film is weak to mechanical shocks, e.g. scratching. Moreover, since the forming process of the multi-laminated protection film is relatively long, such a foreign substance AB can easily be generated during the forming process, and it is lacking in moisture resistance due to such a foreign substance during the forming process, as shown in FIG. 1B.

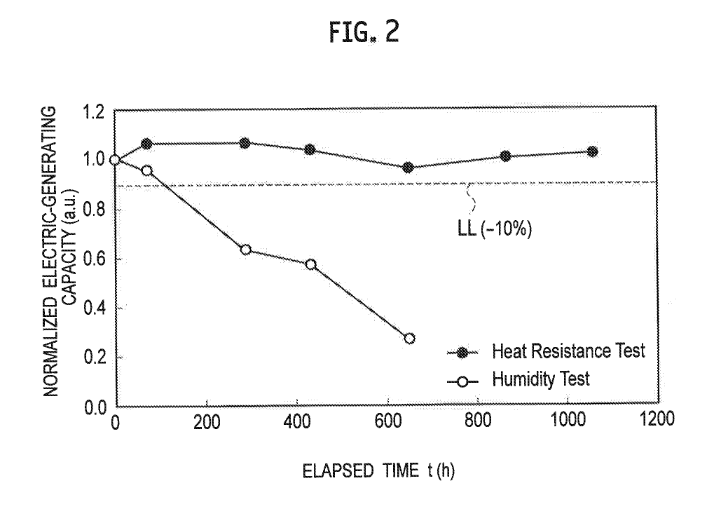

FIG. 2 shows an example of time change characteristics of an electric-generating capacity in a thermal resistance and moisture resistance test [JIS C8938], in the organic thin film photovoltaic device 100A according to the comparative example. A luminosity of fluorescent lamps, 1000 (lux), is applied to an evaluation light source. The heat resistance test was performed at 70 degrees Celsius (C) for 500 hours. The moisture resistance test was performed at a temperature of 60 degrees C. and a humidity of 90% for 500 hours.

In FIG. 2, the black circle plot (•) corresponds to a condition of an ambient temperature of 70 degrees C., and the white circle plot (∘) corresponds to a condition of an ambient temperature of 60 degrees C., and a humidity of 90%. The dashed line LL corresponds to a level to which a normalized maximum electric-generating capacity Pₘₐₓ (a.u.) is reduced by 10% from an initial state.

As a result of the heat resistance test, the normalized maximum electric-generating capacity Pₘₐₓ (a. u.) exceeds the level of the dashed line LL to which Pₘₐₓ (a.u.) is reduced by 10%, during from 0 to 1100 hours (time t (h)), as shown in FIG. 2.

On the other hand, as a result of the moisture resistance test, the normalized maximum electric-generating capacity Pₘₐₓ (a. u.) falls below the level of the dashed line LL to which Pₘₐₓ (a.u.) is reduced by 10%, after the elapse of approximately 100 hours (time t (h)), as shown in FIG. 2.

### (Fabrication Method)

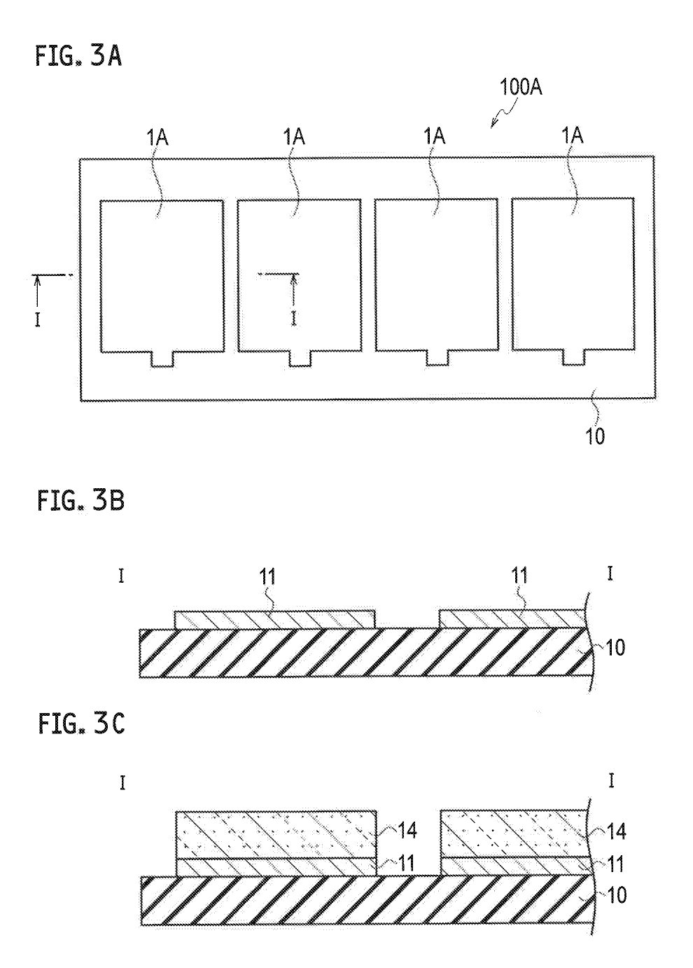

FIG. 3A shows a schematic planar pattern configuration at aside of a light-receiving surface, in a process of a fabrication method of the organic thin film photovoltaic device 100A according to the comparative example. FIG. 3B shows a process of pattern-forming the transparent electrode layer 11 on the substrate 10, corresponding to a schematic cross-sectional structure of a portion taken in the line I-I of FIG. 3A. FIG. 3C shows a process of pattern-forming the organic layer 14 on the transparent electrode layer 11, corresponding to the schematic cross-sectional structure of the portion taken in the line I-I of FIG. 3A.

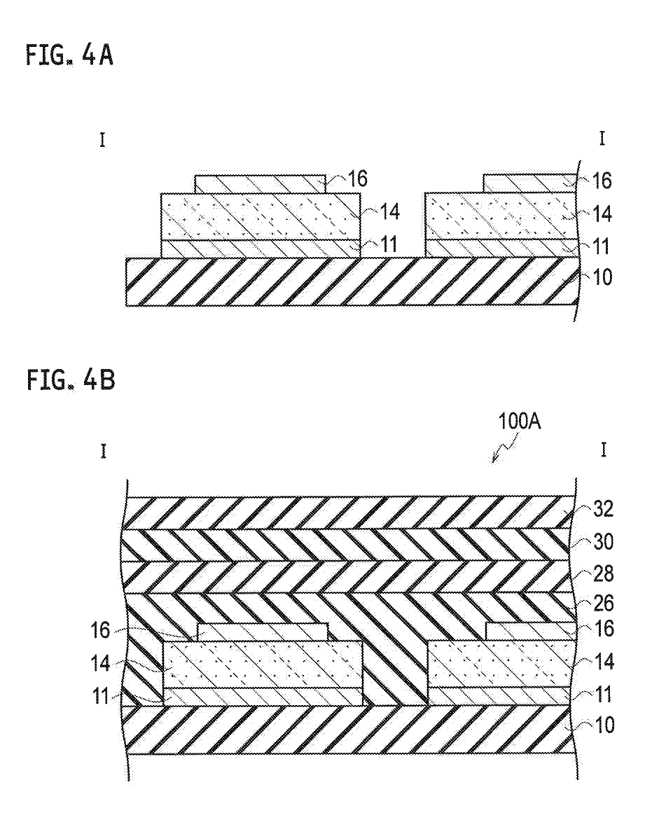

Moreover, FIG. 4A shows a process of pattern-forming the metal electrode layer 16 on the organic layer 14, corresponding to the schematic cross-sectional structure of the portion taken in the line I-I of FIG. 3A, in a process of the fabrication method of the organic thin film photovoltaic device 100A according to the comparative example. FIG. 4B shows a process of forming the passivation layers 26, 28, 30, 32 composed including the multi-layered protection film on the entire surface of the device.

(a) Firstly, as shown in FIG. 3B, the transparent electrode layer (TCO) 11 is patterned by wet etching. In the patterning process of the transparent electrode layer 11, since aqua regia etching using a positive resist requiring long time and much labor is performed, five processes, e.g., approximately 120 minutes, are required therefor.
(b) Next, as shown in FIG. 3C, the organic layer 14 is formed by a film formation with a spin coat method, and by patterning with high-density plasma etching. Since the organic layer 14 is formed having a layered structure of the hole transport layer and the bulk heterojunction organic active layer, process of applying and forming of the organic layer 14 requires two processes, e.g., approximately 60 minutes. In this case, since the spin coat method has inefficient material use and separately coating cannot be directly performed, the patterning process with the high-density plasma etching is required therefor.
(c) Next, as shown in FIG. 4A, aluminum is evaporated with a vacuum evaporation method and thereby the metal electrode layer 16 is formed. The forming of the metal electrode layer 16 requires one process, e.g., approximately 2 minutes. Moreover, while an unnecessary organic layer may be removed by oxygen plasma, an oxide film treatment may be applied to an uppermost surface of the aluminum.
(d) Next, as shown in FIG. 4B, in order to reduce degradation due to moisture and oxygen in the atmosphere, sealing with an SiN film is performed by using CVD technology. In order to eliminate defects, e.g. a spot etc. of the SiN film, and to smooth the back surface of the module, resin material(s) is applied with a spin coat method etc., and then is cured by the UV irradiation. Subsequently, in accordance with required module durability, the multi-laminated protection film including the passivation layers 26, 28, 30, 32 is formed by repeatedly performing the above-mentioned process of operation. The cell sealing with the multi-laminated protection film requires four processes, e.g., approximately 120 minutes.

In the organic thin film photovoltaic device according to the comparative example using the cell sealing with the multi-laminated protection film, the cell sealing shall be performed with the multi-laminated protection film including the inorganic substance and the organic substance, in order to protect the cell from the oxygen and moisture leading to cell degradation. However, there is an advantage that a weight saving of the module is realized since the thickness of the multi-laminated protection film is extremely thin, e.g. approximately 10 μm. However, since the forming of the multi-laminated protection film requires time due to complication thereof, and the multi-laminated protection film is weak to mechanical shocks, e.g. scratching, it is not enough for particularly moisture resistance due to a foreign substance etc. generated during the forming process.

### Embodiment

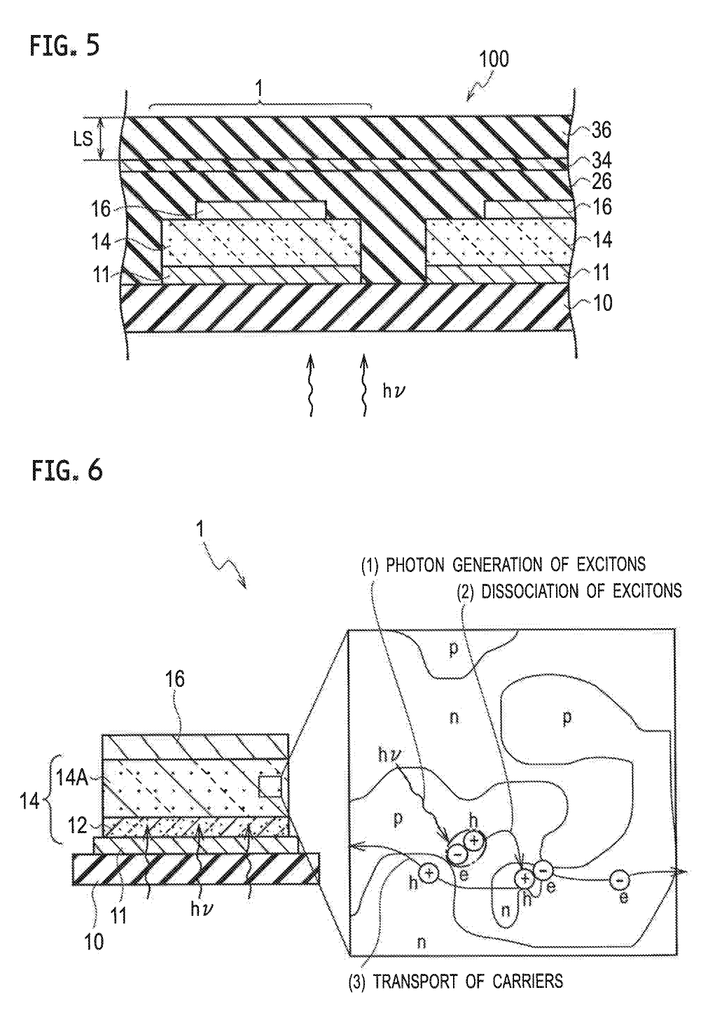

FIG. 5 shows a schematic cross-sectional structure of an organic thin film photovoltaic device 100 and an organic thin film photovoltaic device cell 1, according to the embodiment.

As shown in FIG. 5, the organic thin film photovoltaic device 100 according to the embodiment includes: a substrate 10; an optically transmissive electrode layer 11 disposed on the substrate 10; an organic layer 14 disposed on the transparent electrode layer 11; a metal electrode layer 16 disposed on the organic layer 14; a passivation layer 26 disposed on the metal electrode layer 16; a photo-curing resin layer 34 disposed on the passivation layer 26; and a barrier film 36 disposed on the photo-curing resin layer 34.

The organic thin film photovoltaic device 100 according to the embodiment has a configuration in which the barrier film excellent in durability for sealing the cell with a single-layered protection film is bond thereto using the photo-curing resin, instead of the multi-laminated protection film requiring time due to complication of fabrication thereof.

In the present embodiment, the barrier film 36 may include a sheet glass, for example. The thickness LS of the sheet glass is approximately 50 μm.

The barrier film 36 may include a plastic film, for example.

The passivation layer 26 may include an SiN film or SiON film, for example.

Moreover, the organic thin film photovoltaic device 100 according to the embodiment may include an extraction terminal electrode 2 (+) disposed in a perpendicular-to-plane direction with respect to the substrate 10, the extraction terminal electrode 2 (+) connected to the transparent electrode layer 11 passing through the barrier film 36, the photo-curing resin layer 34, and the passivation layer 26 (refer to FIG. 19).

Alternatively, the organic thin film photovoltaic device 100 according to the embodiment may include an extraction terminal electrode 2 (+) disposed on an edge face of the substrate 10, and the extraction terminal electrode 2 (+) connected to the transparent electrode layer 11 at the edge face (refer to FIG. 21).

Moreover, the organic thin film photovoltaic device 100 according to the embodiment may include a module configuration in which a plurality of organic thin film photovoltaic device cells 1 is connected to one another in series, each of the organic thin film photovoltaic device cells 1 includes: a substrate 10; an optically transmissive electrode layer 11 disposed on the substrate 10; an organic layer 14 disposed on the transparent electrode layer 11; a metal electrode layer 16 disposed on the organic layer 14; a passivation layer 26 disposed on the metal electrode layer 16; a photo-curing resin layer 34 disposed on the passivation layer 26; and a barrier film 36 disposed on the photo-curing resin layer 34.

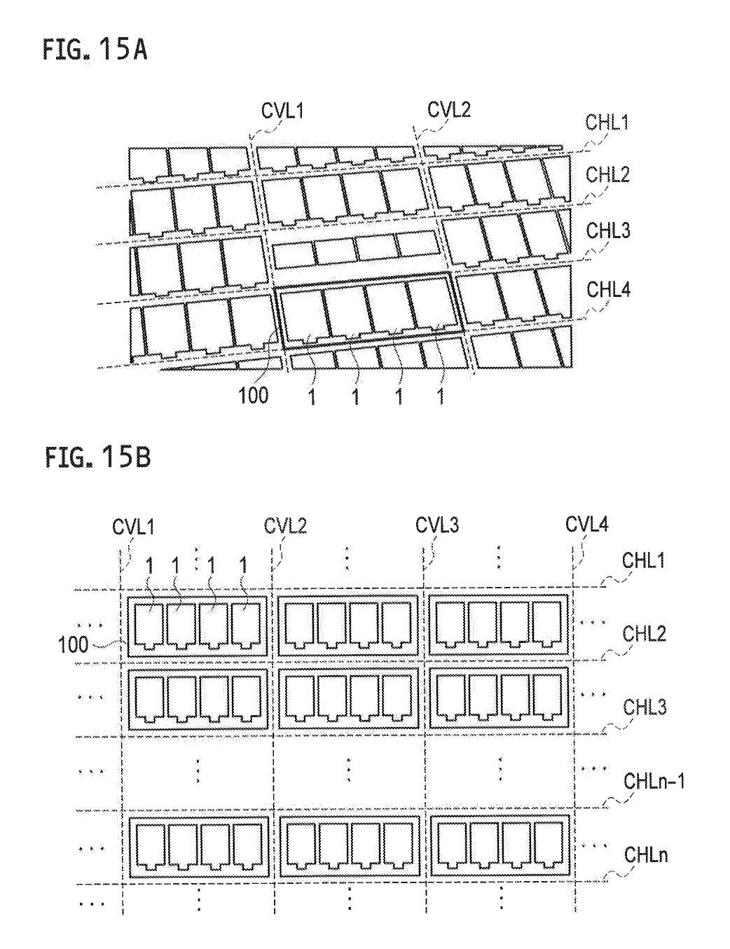

Moreover, the organic layer 14 may include a hole transport layer, and a bulk heterojunction organic active layer disposed on the hole transport layer (refer to FIGS. 15, 18, 20).

As shown in FIG. 5, the organic thin film photovoltaic device 100 according to the embodiment is made by laminating the organic layer 14 having a thickness of approximately several 100 nm used for a power generation layer (photovoltaic layer) on the glass substrate 10 with ITO, and by evaporating metal layers, e.g. an aluminum, as the metal electrode layer 16.

Since a pure aluminum formed as the metal electrode layer 16 is easily oxidized, a passive state film may be formed on a surface thereof in order to improve durability.

Since the organic layers 14, e.g. the hole transport layer, the bulk heterojunction organic active layer, are disposed on the substrate 10, the passive state film formed thereon can prevent the occurrence of damage to the organic layers 14 when forming the passivation layer 26.

The passivation layer 28 disposed on the passivation layer 26 has a role of a protective layer used for the organic thin film photovoltaic device cell 1 according to the embodiment.

In the organic thin film photovoltaic device 100 according to the embodiment, the passivation layer 26 can be formed by a Chemical Vapor Deposition (CVD) method, with an inorganic passivation film, e.g., SiN, SiON, etc.

In the organic thin film photovoltaic device 100 according to the embodiment, the organic thin film photovoltaic device excellent in the durability can be provided by bonding the barrier film 36 excellent in the mechanical strength and the barrier property to the single-layered protection film of the passivation layer 26 with the photo-curing (UV-curing) resin layer 34.

### (Operational Principle)

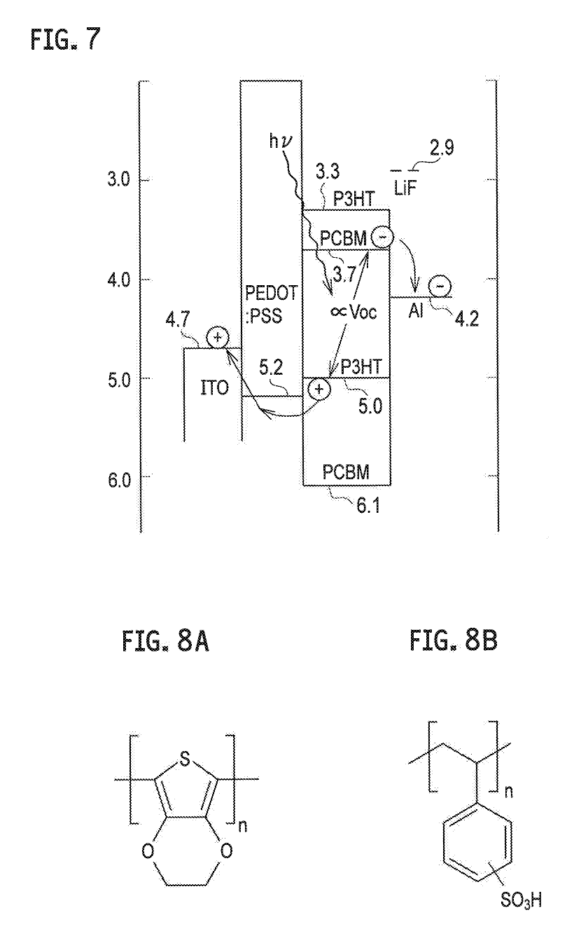

FIG. 6 shows a schematic diagram for explaining an operational principle of the organic thin film photovoltaic device cell 1. Moreover, an energy band structure of various kinds of materials used for the organic thin film photovoltaic device cell 1 shown in FIG. 6 is expressed as shown in FIG. 7. With reference to FIGS. 6 and 7, there will now be explained theoretic configuration and operation of the organic thin film photovoltaic device cell 1 according to the embodiment.

As shown in the left-hand side of FIG. 6, the organic thin film photovoltaic device cell 1 according to the embodiment includes: a substrate 10; an optically transmissive electrode layer 11 disposed on the substrate 10; organic layer 14 (a bulk heterojunction organic active layer 14A, and a hole transport layer 12 disposed on the hole transport layer 12) disposed on the transparent electrode layer 11; and a metal electrode layer 16 disposed on the organic layer 14. The metal electrode layer 16 is formed of aluminum (Al), for example, and used for cathode electrode layer.

In this case, the bulk heterojunction organic active layer 14A forms a complicated bulk hetero pn junction such that p type organic active layer regions and n type organic active layer regions are existed, as shown in the right-hand side of FIG. 6. In the embodiment, a p type organic active layer region is formed of P3HT (poly (3-hexylthiophene-2,5diyl)), for example, and an n type organic active layer region is formed of PCBM (6,6-phenyl-C61-butyric acid methyl ester), for example.

(a) Firstly, when light is absorbed, photon generation of excitons occur in the bulk heterojunction organic active layer 14A.
(b) Next, the excitons are dissociated to free carriers of electrons (e−) and holes (h+) by spontaneous polarization, in the pn junction interfaces in the bulk heterojunction organic active layer 14A.
(c) Next, the dissociated holes (h+) travel towards the optically transmissive electrode layer 11 acting as an anode electrode, and the dissociated electrons (e−) travel towards the cathode electrode layer 16.
(d) As a result, between the cathode electrode layer 16 and the optically transmissive electrode layer 11, a reverse current conducts and an open circuit voltage V_{oc} occurs, and thereby the organic thin film photovoltaic device cell 1 can be obtained.

In the organic thin film photovoltaic device cell 1, a chemical structural formula of PEDOT is expressed as shown in FIG. 8A, and a chemical structural formula of PSS is expressed as shown in FIG. 8B, among PEDOT:PSS applied to the hole transport layer 12.

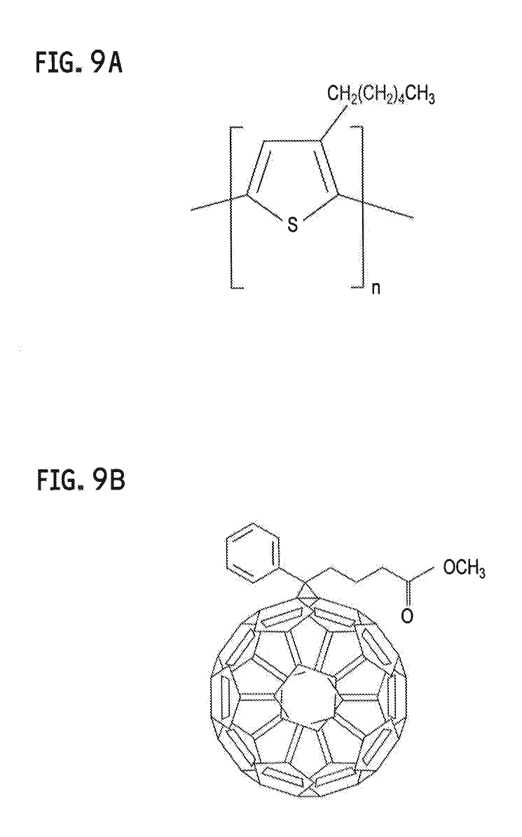

In the organic thin film photovoltaic device cell 1 according to the embodiment, a chemical structural formula of P3HT applied to the bulk heterojunction organic active layer 14A is expressed as shown in FIG. 9A, and a chemical structural formula of PCBM applied to the bulk heterojunction organic active layer 14A is expressed as shown in FIG. 9B.

The passive state film is composed including an oxide film of the metal electrode layer 16. Moreover, the oxide film of the metal electrode layer 16 can be formed with oxygen plasma treatment applied on the surface of the metal electrode layer 16. The thickness of the passive state film is from approximately 10 angstroms to approximately 100 angstroms, for example.

The metal electrode layer 16 may be composed including any one of metals, such as Al, W, Mo, Mn, or Mg. If the metal electrode layer 16 is formed including Al, the passive state film is an alumina (Al₂O₃) film.

Even in the case where moisture or oxygen is infiltrated into the organic layer 14, the organic thin film photovoltaic device cell 1 including the passive state film on the surface of the metal electrode layer 16 can prevent a situation where the metal electrode layer 16 is oxidized due to the moisture or oxygen. Accordingly, degradation of the organic solar cell can be reduced, thereby improving the durability thereof.

### (Gas Barrier Characteristics)

An example of a sheet glass of 50 μm in thickness applied to the organic thin film photovoltaic device according to the embodiment satisfies a grade of gas barrier characteristics required for solar cells.

(Scratching Test with Tweezers)

Although a crack had occurred as a result of the scratching test with tweezers in the cell sealing with the multi-laminated protection film according to the comparative example, no crack has occurred as a result of the scratching test with tweezers in the cell sealing with the sheet glass.

### (Thermal Resistance and Moisture Resistance Test)

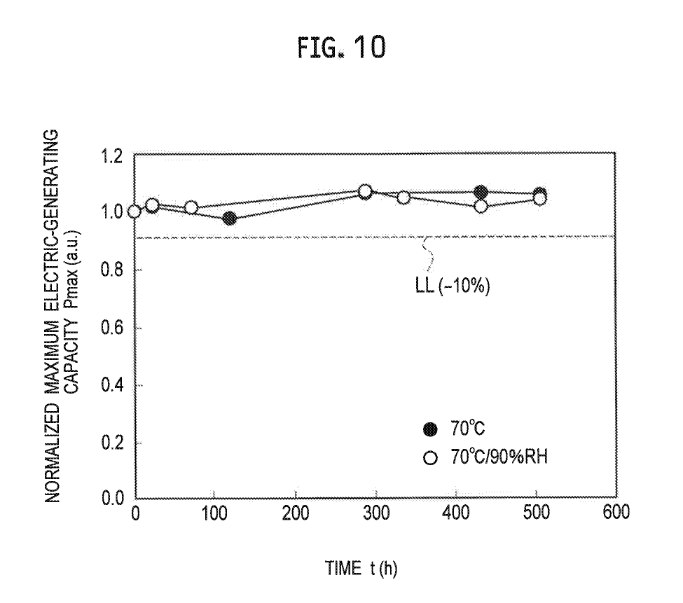

FIG. 10 shows time change characteristics of an electric-generating capacity in a thermal resistance and moisture resistance test, in the organic thin film photovoltaic device according to the embodiment. A luminosity of fluorescent lamps, 1000 (lux), is applied to an evaluation light source.

The heat resistance test was performed at 70 degrees C. for 500 hours.

The moisture resistance test was performed at a temperature of 60 degrees C. and a humidity of 90% for 500 hours.

In FIG. 10, the black circle plot (•) corresponds to a condition of an ambient temperature of 70 degrees C., and the white circle plot (∘) corresponds to a condition of an ambient temperature of 60 degrees C., and a humidity of 90%. The dashed line LL corresponds to a level to which a normalized maximum electric-generating capacity Pₘₐₓ (a.u.) is reduced by 10% from an initial state. The normalized maximum electric-generating capacity Pₘₐₓ (a. u.) exceeds the level of the dashed line LL to which Pₘₐₓ (a.u.) is reduced by 10%, during from 0 to 500 hours (time t (h)), as shown in FIG. 10.

The organic thin film photovoltaic device according to the embodiment satisfies sufficiency levels of both of the heat resistance test at the ambient temperature of 70 degrees C., and the moisture resistance test at the ambient temperature of 70 degrees C. and the humidity of 90%.

### (Light Continuous Irradiation Test)

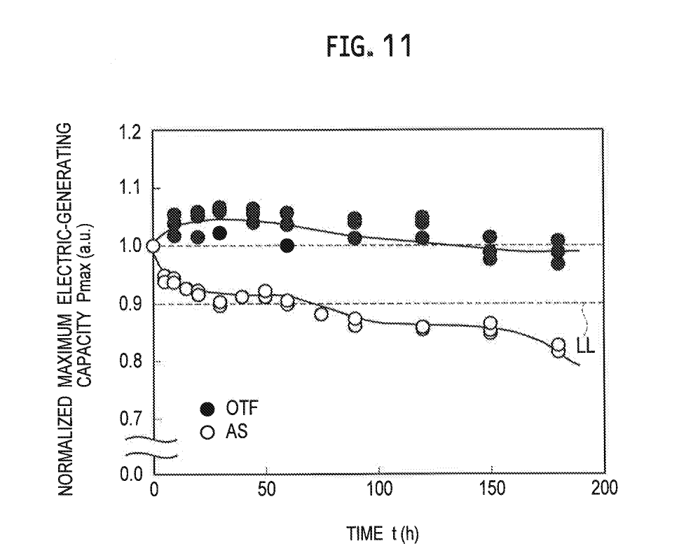

FIG. 11 shows time change characteristics of an electric-generating capacity in a light continuous irradiation test, in the organic thin film photovoltaic device according to the embodiment. As a test light source, a light source having 35 mW/cm² (wavelength λ=365 nm) is used, and a luminosity of fluorescent lamps, 1000 (lux), is applied to an evaluation light source.

In the light continuous irradiation test, continuous light irradiation was performed for 180 minutes.

In FIG. 11, black circle plot (•) OTF corresponds to an organic thin film photovoltaic device according to the embodiment, and white circle plot (∘) AS corresponds to an amorphous-silicon solar cell.

In the amorphous-silicon solar cell, the normalized maximum electric-generating capacity Pₘₐₓ (a. u.) exceeds the level of dashed line LL to which Pₘₐₓ (a.u.) is reduced by 10%, during from 0 to 50 hours (time t (h)), but is reduced by 10% or more after the elapse of approximately 50 hours (time t (h)), as shown in FIG. 11.

On the other hand, in the organic thin film photovoltaic device according to the embodiment, the normalized maximum electric-generating capacity Pₘₐₓ (a. u.) has approximately flat characteristics, during from 0 to 180 hours (time t (h)), as shown in FIG. 11.

As shown in FIG. 11, the organic thin film photovoltaic device according to the embodiment satisfies a sufficiency level of the light continuous irradiation test, and therefore has sufficiently light resistance.

The organic thin film photovoltaic device according to the embodiment is excellent in thermal and moisture resistances, scratching resistance, and light tolerance, by adopting the barrier film having the high barrier property into the cell sealing.

### (Fabrication Method)

The organic thin film photovoltaic device 100 according to the embodiment is formed by laminating approximately several 100-nm organic layer 14 used for a power generation layer (photovoltaic layer) on the glass substrate 10 with ITO, and then evaporating a metal, e.g. aluminum. Since pure aluminum formed as the metal electrode layer is easily oxidized, the organic thin film photovoltaic device excellent in the durability can be provided by bonding the barrier film 36 excellent in the mechanical strength and the barrier property to the single-layered protection film of the passivation layer 26, e.g. SiN or SiON, by CVD, with the photo-curing (UV-curing) resin layer 34, in order to give a durability.

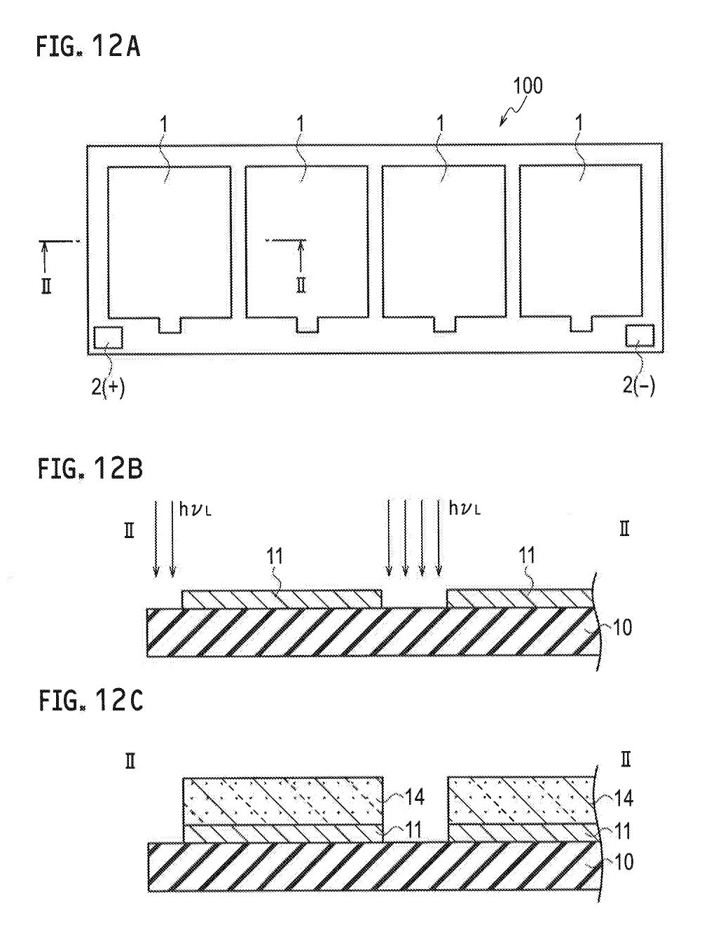

In a process of the fabrication method of the organic thin film photovoltaic device 100 according to the embodiment: FIG. 12A shows a schematic planar pattern configuration at a side of a terminal-extracting surface; FIG. 12B shows a process of pattern-forming the transparent electrode layer 11 on the substrate 10, corresponding to a schematic cross-sectional structure of a portion taken in the line II-II of FIG. 12A; and FIG. 12B shows a process of pattern-forming the organic layer 14 on the transparent electrode layer 11.

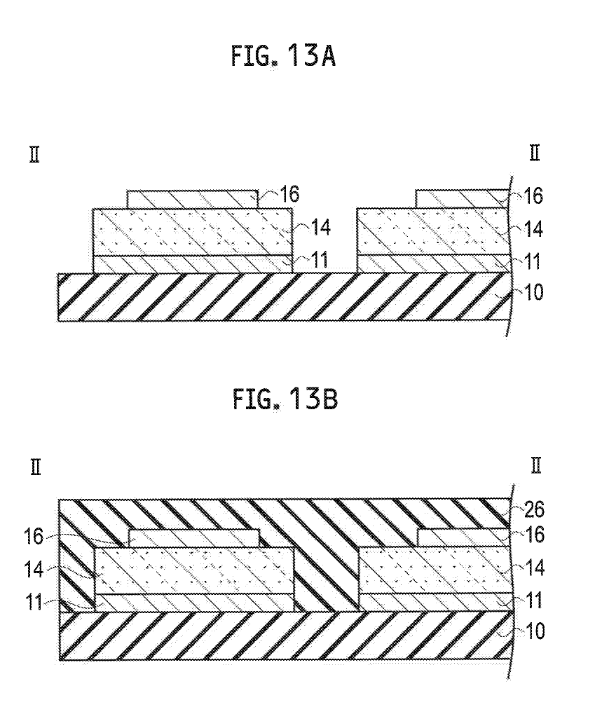

Moreover, in a process of the fabrication method of the organic thin film photovoltaic device 100 according to the embodiment, FIG. 13A shows a process of pattern-forming the metal electrode layer 16 on the organic layer 14, corresponding to the schematic cross-sectional structure of the portion taken in the line II-II of FIG. 12A. FIG. 13B shows a process of forming the passivation layer 26 the entire surface of the device.

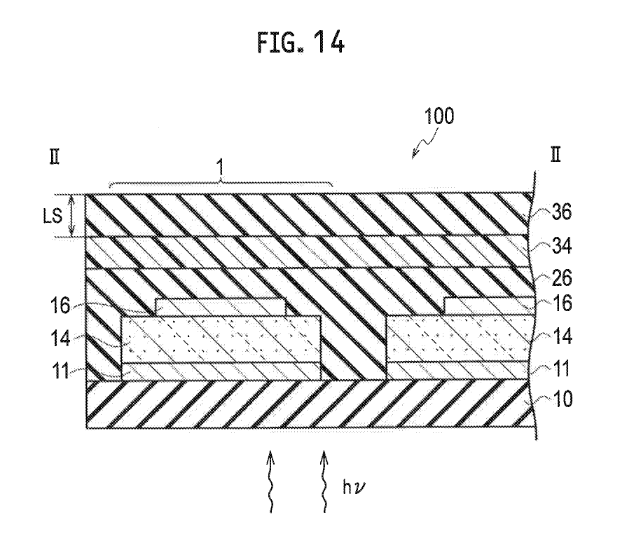

Furthermore, FIG. 14 shows a process of bonding the barrier film 36 via the photo-curing resin layer 34 on the passivation layer 26, corresponding to the schematic cross-sectional structure of the portion taken in the line II-II of FIG. 12A, in a process of the fabrication method of the organic thin film photovoltaic device 100 according to the embodiment.

Furthermore, FIG. 15A shows a schematic bird's-eye configuration of an organic thin film photovoltaic device module having a 4-cells serial structure disposed on the substrate 10 in a matrix shape, in a process of the fabrication method of the organic thin film photovoltaic device 100 according to the embodiment. A module dicing process is expressed as shown in FIG. 15B.

As shown in FIGS. 12 to 14, the fabrication method of the organic thin film photovoltaic device 100 according to the embodiment includes: forming a transparent electrode layer 11 on a substrate 10; forming an organic layer 14 on the transparent electrode layer 11; forming a metal electrode layer 16 on the organic layer 14; forming a passivation layer 26 on the metal electrode layer 16; and forming a barrier film 36 via a photo-curing resin layer 34 on the passivation layer 26.

The barrier film 36 may include a sheet glass.

The barrier film 36 may include a plastic film.

Moreover, the fabrication method of the organic thin film photovoltaic device 100 according to the embodiment may include forming an extraction terminal electrode 2 (+) disposed in a perpendicular-to-plane direction with respect to the substrate 10, the extraction terminal electrode 2 connected to the transparent electrode layer 11, passing through the barrier film 36, the photo-curing resin layer 34, and the passivation layer 26.

Moreover, the fabrication method of the organic thin film photovoltaic device 100 according to the embodiment may include forming an extraction terminal electrode 2 (+) disposed on an edge face of the substrate, the extraction terminal electrode 2 (+) connected to the transparent electrode layer 11 at the edge face.

Moreover, the process of the forming the organic layer 14 may include formation process with a spin coat method or an ink-jet process.

Moreover, the process of the forming the organic layer 14 may include forming a hole transport layer, and forming a bulk heterojunction organic active layer on the hole transport layer.

Moreover, the fabrication method of the organic thin film photovoltaic device 100 according to the embodiment may include forming a passive state film on a surface of the metal electrode layer.

With reference to FIGS. 12-15, there will now be explained the fabrication method of the organic thin film photovoltaic device according to the embodiment, in which a plurality (four pieces, as an example in the figures) of the organic thin film photovoltaic devices is arranged in series.

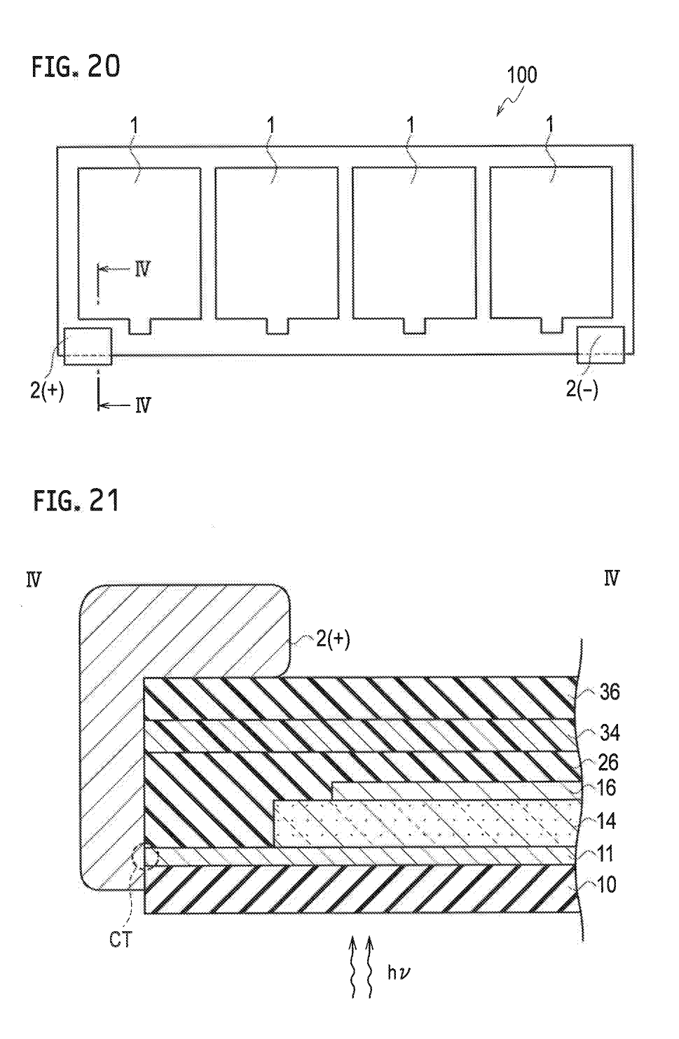

(a) Firstly, a glass substrate (of which the size is, for example, 50 mm in length×50 mm in width×0.7 mm in thickness) washed by pure water, acetone and ethanol is inserted into an Inductively Coupled Plasma (ICP) etcher, and adherents on the surface of the glass substrate are removed by O₂ plasma (Glass Substrate Surface Treatment). In order to efficiently guide the light to the organic layer, an antireflection process may be performed to the glass surface of the substrate 10 formed of a glass substrate. An alkali-free glass substrate with ITO may be used as the glass substrate, for example.
(b) Next, as shown in FIG. 12B, the optically transmissive electrode layer 11 composed of, for example, ITO is pattern-formed on the glass substrate 10. Specifically, the TCO is patterned by wet etching, such as aqua regia etching, using a positive resist, for example. The patterning of the transparent electrode layer 11 requires five processes, e.g., approximately 120 minutes. As a consequence, a plurality of the transparent electrode layers 11 are formed in a stripe pattern so as to sandwich a trench region. A laser patterning technology etc. are also applicable to the forming of the trench.
(c) Next, as shown in FIG. 12C, the organic layer 14 (the hole transport layer 12 and the bulk heterojunction organic active layer 14A) is formed on each transparent electrode layer 11. The process of applying and forming of the organic layer 14 requires two processes, e.g., approximately 60 minutes. For example, the process of applying and forming of the organic layer 14 includes a film formation by a spin coat method, spray technology, screen printing technology, etc., and a patterning process by high-density plasma etching.
(c-1) Spin coating technology, spray technology, screen printing technology, etc. can be applied to the formation of the hole transport layer 12. In this case, in the process for forming the hole transport layer 12, the film formation is performed, for example, by spin coating of PEDOT:PSS, and annealing is applied thereto for approximately 10 minutes at 120 degrees C. for the purpose of water removal. Oxygen plasma etching technology, laser patterning technology, nano-imprint technology, etc. can be applied to the formation of the trench region.
(c-2) Next, the bulk heterojunction organic active layer 14A is formed on each hole transport layer 12. In the formation process of the bulk heterojunction organic active layer 14A, film formation is performed with spin coating of P3HT, for example.
(d) Next, as shown in FIG. 13A, the metal electrode layer (cathode electrode layer) 16 is pattern-formed on the organic layer 14. The metal electrode layer 16 is formed by depositing a metal layer (e.g., Al, W, Mo, Mn, Mg) by vacuum thermal vapor deposition, for example. Screen printing technology instead of the vacuum thermal vapor deposition may be applied to the formation of the cathode electrode layer 16. The formation process of the metal electrode layer 16 requires one process, e.g., approximately 2 minutes.
(e) Next, although illustration is omitted, after performing an etching process of the unnecessary organic layer 14, an oxide film (passive state film) may be formed on a surface of the metal electrode layer 16. The passive state film can be formed by applying oxygen plasma treatment to the metal electrode layer 16. The passive state film can be formed using a high-density plasma etching apparatus, for example. It is also possible to perform an etching process of the organic layer 14 at the same time when the passive state film is formed by performing the oxygen plasma treatment of the metal electrode layer 16.
(f) Next, as shown in FIG. 13B, the passivation layer 26 is formed on the entire surface of the device. In this case, the passivation layer 26 may be formed of a silicon nitride film etc. with the CVD. The thickness of the silicon nitride film is approximately 0.5 μm to approximately 1.5 μm, for example. Durability can be further improved by sealing with the SiN film formed by using CVD to reduce degradation due to moisture or oxygen in atmospheric air.
(g) Next, as shown in FIG. 14, the barrier film 36 is bonded on the passivation layer 26 via the photo-curing resin layer 34. In order to eliminate defects, such as a spot, of the passivation layer 26 formed with the SiN film, and to smooth the back surface of the module, the photo-curing (UV-curing) resin layer 34 is coated with a spin coat method etc., then is cured by the UV irradiation after the barrier film 36 is bonded. In the organic thin film photovoltaic device according to the embodiment, the durability can be secured by adoption of the barrier film, the number of the processes of the multi-laminated protection film can be significantly reduced from four processes, e.g., 120 minutes, to two processes, e.g., 60 minutes.
(h) Next, as shown in FIGS. 15A and 15B, the organic thin film photovoltaic device module having the 4-cells serial structure disposed in the matrix shape on the substrate 10 is scribed along longitudinal scribe lines CVL1, CVL2, CVL3, CVL4, . . . , and horizontal scribe lines CHL1, CHL2, CHL3, . . . , CVL4, . . . , CHLn-1, . . . , CHLn.
(i) Next, as shown in FIG. 19 or 20, the terminal electrode 2 (+) is extracted therefrom.
(i-1) More specifically, as shown in FIG. 19, the extraction terminal electrode 2 (+) disposed in a perpendicular-to-plane direction with respect to the substrate 10 and connected to the transparent electrode layer 11 may be formed through a contact hole formed passing through the barrier film 36, the photo-curing resin layer 34, and the passivation layer 26.
(i-2) Alternatively, as shown in FIG. 20, the extraction terminal electrode 2 (+) may be formed so as to be connected to the transparent electrode layer 11 at the edge face of the substrate 10.
(j) Next, although illustration is omitted, a bonding junction between an anode terminal A electrode and a cathode terminal K electrode of the organic thin film photovoltaic device connected in series is formed. Carbon paste, Ag paste, etc. are used for the bonding junction, for example. The terminal electrode can be formed including a gold wire etc., for example.
(k) Finally, although illustration is omitted, the entire device may be protected with a UV curing resin etc., from an intrusion of moisture, oxygen, etc.

According to the above-mentioned processes, the plurality (four pieces in the example in the figures) of the organic thin film photovoltaic devices 100 according to the embodiment arranged in series can be completed.

In the organic thin film photovoltaic device 100 according to the embodiment, there can be provided: the organic thin film photovoltaic device, of which the fabrication process is simplified and the durability is excellent, by bonding the barrier film 36 excellent in the mechanical strength and the barrier property on the single-layered protection film of the passivation layer 26 with the photo-curing (UV-curing) resin layer 34; and the fabrication method of such an organic thin film photovoltaic device.

### (Heat-Resistant (High Temperature Preservation) Test)

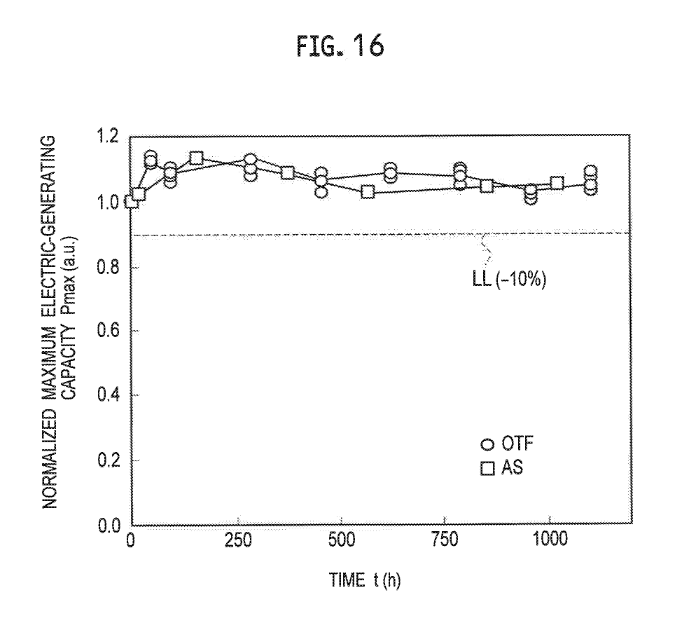

FIG. 16 shows time change characteristics of an electric-generating capacity in a heat-resistant (high temperature preservation) test, in the organic thin film photovoltaic device according to the embodiment. JIS C 8938B-1 is applied to a test specification, and a preservation temperature is 85 degrees C. In FIG. 16, the white circle plot (•) OTF corresponds to the organic thin film photovoltaic device according to the embodiment, and the square shape (□) AS corresponds to the amorphous-silicon solar cell. A luminosity of fluorescent lamps, 1000 (lux), is applied to an evaluation light source. Moreover, the shape of the evaluation element has a 4-cells serial structure.

In the amorphous-silicon solar cell, the normalized maximum electric-generating capacity Pₘₐₓ (a. u.) has approximately flat characteristics, during from 0 to 1000 hours (time t (h)), as shown in FIG. 16.

On the other hand, also in the organic thin film photovoltaic device according to the embodiment, the normalized maximum electric-generating capacity Pₘₐₓ (a. u.) has approximately flat characteristics, during from 0 to 1000 hours (time t (h)), as shown in FIG. 16.

As shown in FIG. 16, the organic thin film photovoltaic device according to the embodiment satisfies a sufficiency level of the heat-resistant (high temperature preservation) test, and therefore has sufficiently thermal resistance.

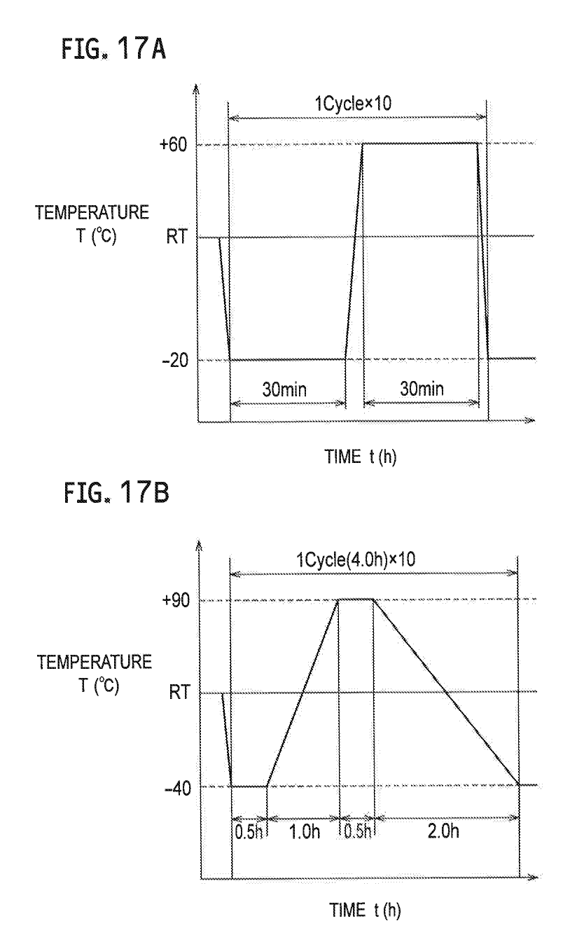

In the organic thin film photovoltaic device according to the embodiment, FIG. 17A shows an example of a temperature profile applied to a thermal shock cycle test, and FIG. 17B shows an example of a temperature profile applied to a temperature cycle test.

As shown in FIG. 17A, 10 cycles of rapid cooling and rapid heating cycling from −20 degrees C. for 30 minutes to +60 degrees C. for 30 minutes are performed, in the thermal shock cycle test.

In the temperature cycle test, as shown in FIG. 17B, 10 cycles (4 hours per a cycle) of temperature changing from −20 degrees C. to +90 degrees C. are performed.

In the organic thin film photovoltaic device according to the embodiment, changing ranges not more than 10% are provided from initial characteristics after completing of the tests also in each of test items of the thermal shock test, the temperature cycle test, the light irradiation test, the heat resistance test, and the moisture resistance test, and therefore each test item satisfies the sufficiency level.

### (Terminal Extracting Structure)

In the organic thin film photovoltaic device according to the embodiment, the process can be simplified and the durability can be secured by bonding the barrier film 36 excellent in the mechanical strength and the barrier property onto the passivation layer 26 including the single layer inorganic protection film with the UV curing resin layer 34, in order to protect the cell from oxygen and moisture leading to deterioration of the cell.

### —Contact Hole Type—

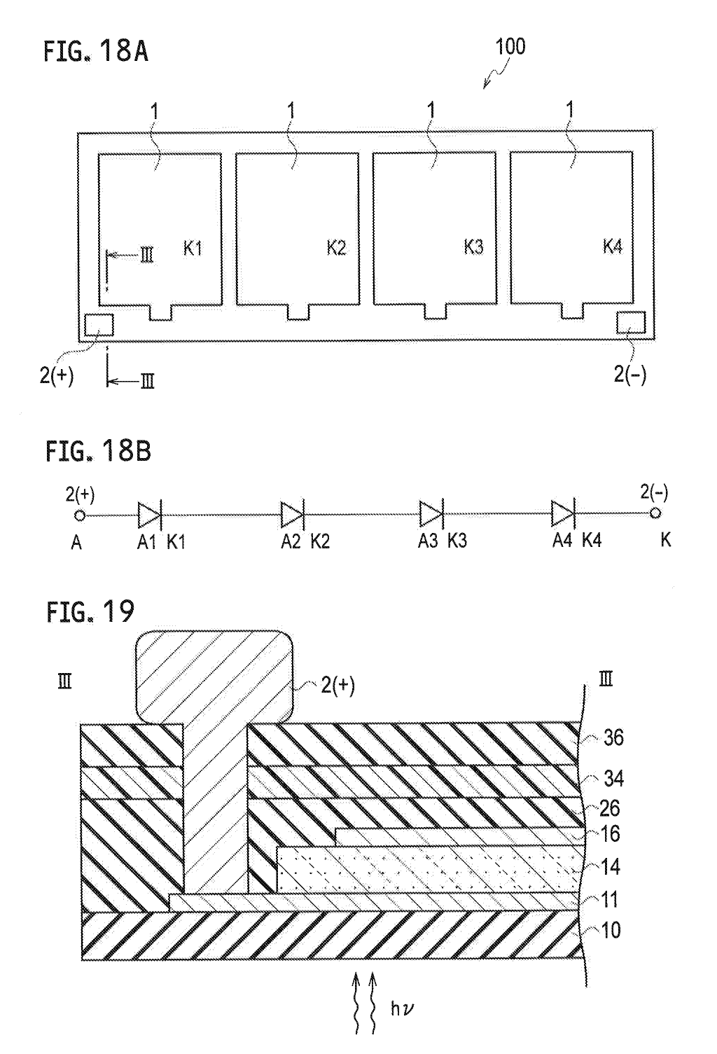

In the organic thin film photovoltaic device according to the embodiment, FIG. 18A shows a schematic planar pattern configuration at a side of a terminal-extracting surface of the organic thin film photovoltaic device module having a 4-cells serial structure, and FIG. 18B shows an equivalent circuit representation of the organic thin film photovoltaic device module having the 4-cells serial structure. Moreover, FIG. 19 shows a schematic cross-sectional structure taken in the line of FIG. 18A.

In the above-mentioned embodiment, when extracting an output terminal, the barrier film 36 is excavated by a microneedle in order to form a contact hole, and the contact hole is further filled up with conductive paste etc., and thereby the output terminal electrode 2 (+) is formed.

### —Edge Face Contact Type—

On the other hand, in the organic thin film photovoltaic device according to a modified example of the embodiment, FIG. 20 shows a schematic planar pattern configuration at a side of a terminal-extracting surface of the organic thin film photovoltaic device module having a 4-cells serial structure, and FIG. 21 shows a schematic cross-sectional structure taken in the line IV-IV of FIG. 20.

In the example shown in FIGS. 20 and 21, the output terminal electrode 2 (+) can be extracted from a module-cutting edge face. More specifically, the output terminal electrode 2 (+) is disposed on the module-cutting edge face, and a contact between the output terminal electrode 2 (+) and the transparent electrode layer 11 can be taken at an edge face portion CT.

Even if the barrier film 36 is damaged at the time of excavating, and it is difficult to secure a durability thereof due to a crack of the barrier film 36, a yield rate can be improved due to such an electrode extraction structure through edge face.

In the modified example of the embodiment, the transparent electrode layer 11 is disposed on the module-cutting edge face, the contact is formed at the edge face portion CT with the conductive paste, and thereby the output terminal electrode 2 (+) at the barrier film plane or glass substrate surface can be extracted therefrom, instead of a shape in which the barrier film 36 tends to be cracked when forming the contact hole. In the present embodiment, room-temperature-drying type Ag paste etc. are applicable, as the conductive paste, for example.

In the organic thin film photovoltaic device according to the modified example of the embodiment, since no contact hole is formed, a possibility of crack of the barrier film 36 is reduced. Moreover, the durability, in particular moisture resistance, can be improved, since an edge left for sealing can be increased.

### (Result of Moisture Resistance Test)

The moisture resistance test was performed at a temperature of 60 degrees C. and a humidity of 90% for 500 hours. A luminosity of fluorescent lamps, 1000 (lux), 0.106 mW/cm², is applied to an evaluation light source. Moreover, the shape of the evaluation element has a 4-cells serial structure. P3HT:60PCBM is formed for an active layer by spin coating.

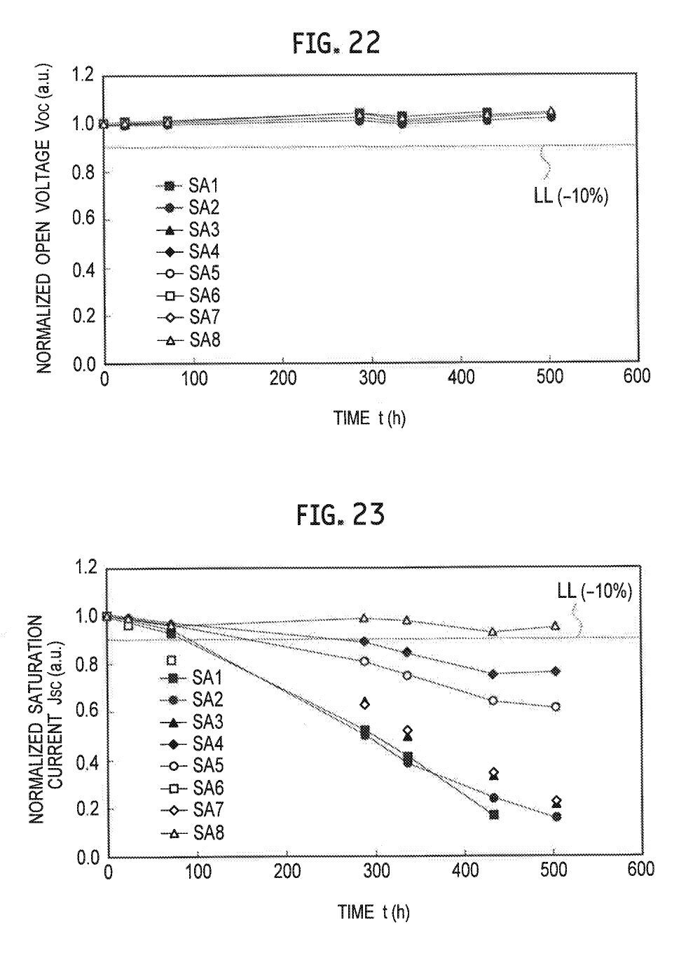

FIG. 22 shows time change characteristics of a normalized open voltage V_{oc} (a.u.), in a result (relative values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The dashed line LL corresponds to a level to which the normalized open voltage V_{oc} (a.u.) is reduced by 10% from an initial state. The normalized open voltage V_{oc} (a.u.) exceeds the level of the dashed line LL to which the V_{oc} (a.u.) is reduced by 10%, during from 0 to 500 hours (time t (h)), as shown in FIG. 22.

FIG. 23 shows time change characteristics of a normalized saturation current J_{sc} (a. u.), in a result (relative values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The dashed line LL corresponds to a level to which the normalized saturation current J_{sc} (a. u.) is reduced by 10% from an initial state. The sample SA8 of the normalized saturation current J_{sc} (a. u.) exceeds the level of the dashed line LL to which the J_{sc} (a. u.) is reduced by 10%, during from 0 to 500 hours (time t (h)), as shown in FIG. 23.

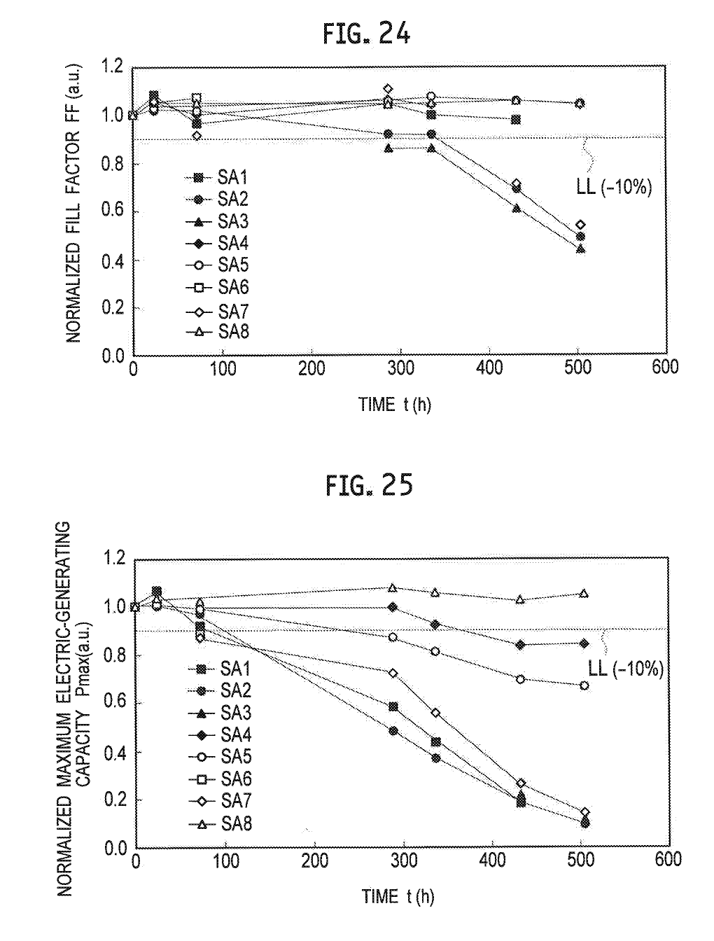

FIG. 24 shows time change characteristics of a normalized fill factor FF (a. u.), in a result (relative values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The dashed line LL corresponds to a level to which the normalized fill factor FF (a. u.) is reduced by 10% from an initial state. The samples SA1, SA4, SA5, SA6, and SA8 of the normalized fill factor FF (a. u.) exceed the level of the dashed line LL to which the normalized fill factor FF (a. u.) is reduced by 10%, during from 0 to 500 hours (time t (h)), as shown in FIG. 24.

FIG. 25 shows time change characteristics of a normalized maximum electric-generating capacity Pₘₐₓ (a.u.), in a result (relative values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The dashed line LL corresponds to a level to which the normalized maximum electric-generating capacity Pₘₐₓ (a.u.) is reduced by 10% from an initial state. The sample SA8 of the normalized maximum electric-generating capacity Pₘₐₓ (a.u.) exceeds the level of the dashed line LL to which the Pₘₐₓ (a.u.) is reduced by 10%, during from 0 to 500 hours (time t (h)), as shown in FIG. 25.

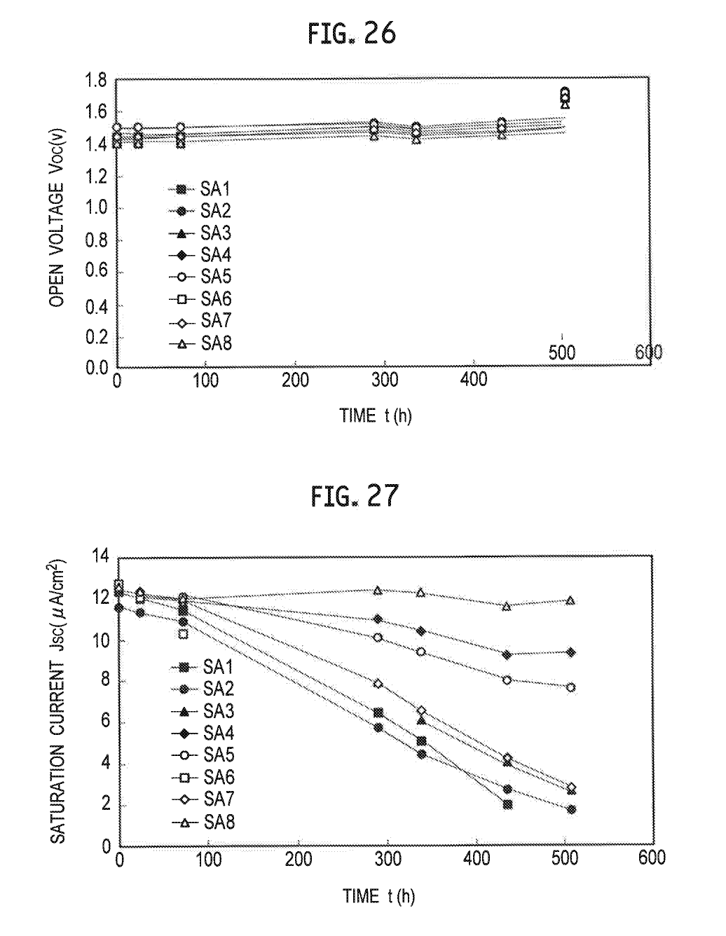

FIG. 26 shows time change characteristics of an open voltage V_{oc} (V) in a result (absolute values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The samples SA1-SA8 of the open voltage V_{oc} (V) exceeds the level of the dashed line LL to which the V_{oc} (V) is reduced by 10%, during from 0 to 500 hours (time t (h)), as shown in FIG. 26.

FIG. 27 shows time change characteristics of a saturation current J_{sc} (μA/cm²), in a result (absolute values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The sample SA8 of the saturation current J_{sc} (μA/cm²) indicates satisfactory characteristics, during from 0 to 500 hours (time t (h)), as shown in FIG. 27.

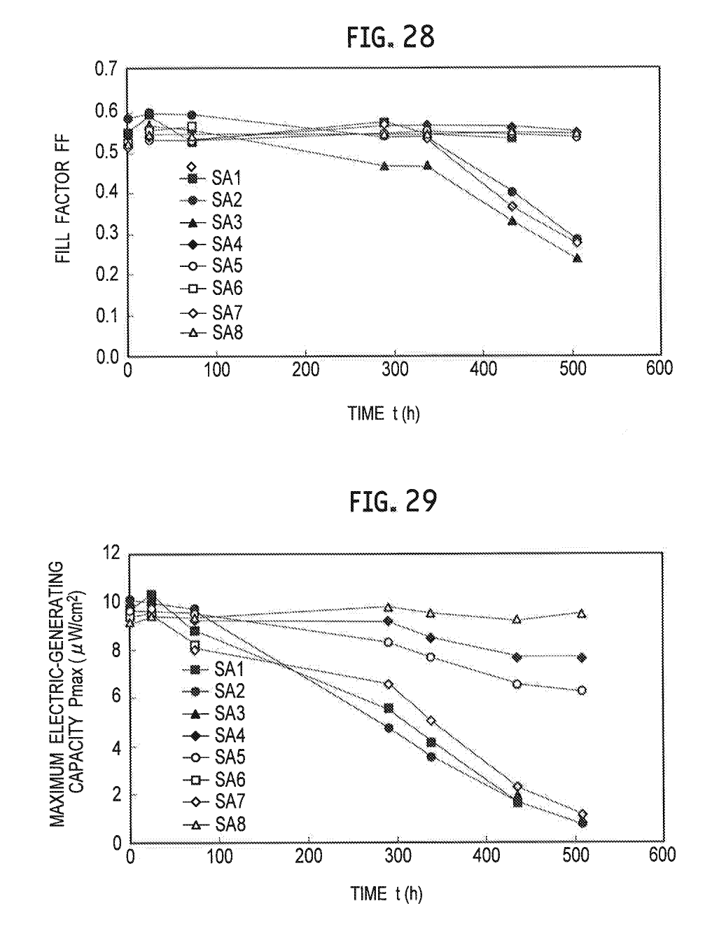

FIG. 28 shows time change characteristics of a fill factor FF, in a result (absolute values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The samples SA1, SA4, SA5, SA6, and SA8 of the normalized fill factor FF indicates satisfactory characteristics, during from 0 to 500 hours (time t (h)), as shown in FIG. 28.

FIG. 29 shows time change characteristics of a maximum electric-generating capacity Pₘₐₓ (μW/cm²), in a result (absolute values) of the moisture resistance test (environmental test) of the organic thin film photovoltaic device modules according to the embodiment and its modified example. In this case, the samples SA1-SA7 have an electrode extracting structure through contact hole, and the sample SA8 has an electrode extraction structure through edge face. The sample SA8 of the maximum electric-generating capacity Pₘₐₓ (μW/cm²) indicates satisfactory characteristics, during from 0 to 500 hours (time t (h)), as shown in FIG. 29.

The organic thin film photovoltaic devices according to the embodiment and its modified example satisfy sufficiency levels of both of the heat resistance test at the ambient temperature of 70 degrees C., and the moisture resistance test at the ambient temperature of 60 degrees C. and the humidity of 90%.

### (Organic Thin Film Photovoltaic Device Module Having 4-Cells Serial Structure)

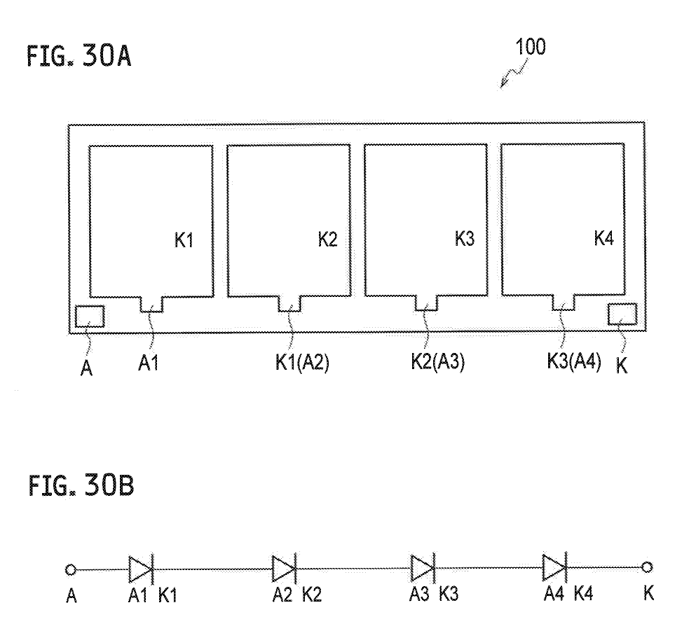

In the organic thin film photovoltaic device 100 according to the embodiment, FIG. 30A shows a plane configuration for explaining an electrode connection relationship at a side of a terminal-extracting surface of the organic thin film photovoltaic device module having the 4-cells serial structure, and FIG. 30B shows an equivalent circuit representation corresponding to FIG. 30A.

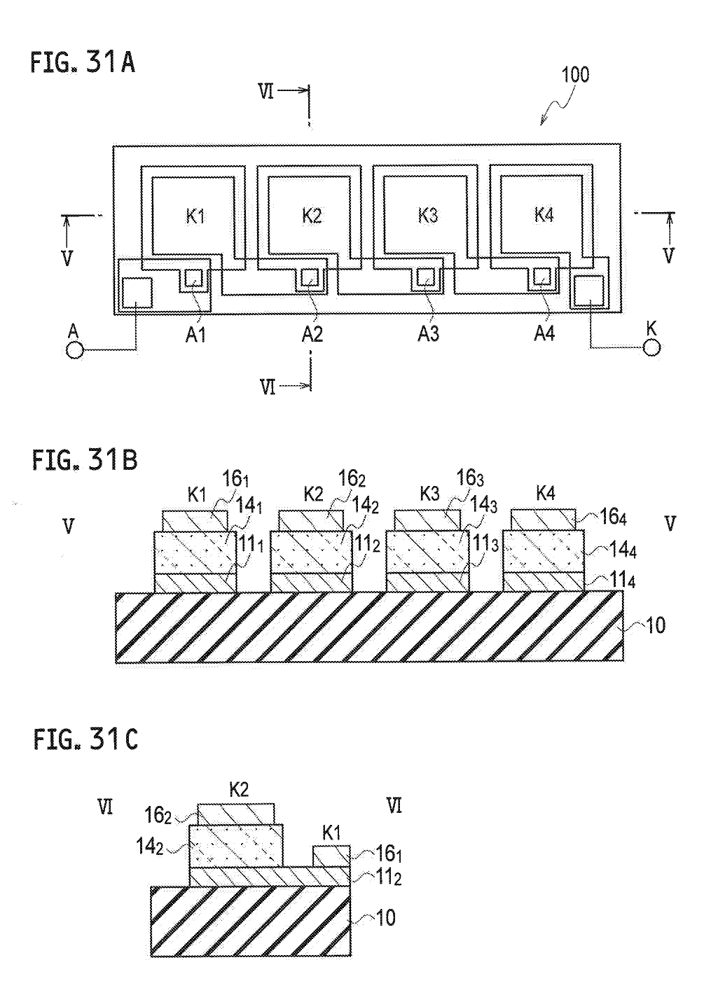

FIG. 31A shows a schematic plane configuration of cathode electrodes K1, K2, K3, K4 and anode electrodes A1, A2, A3, A4 at a side of a terminal-extracting surface of the organic thin film photovoltaic device module having the 4-cells serial structure, in the organic thin film photovoltaic device according to the embodiment. FIG. 31B shows a schematic cross-sectional structure taken in the line V-V of FIG. 31A, and FIG. 31C shows a schematic cross-sectional structure taken in the line VI-VI of FIG. 31A.

In each organic thin film photovoltaic device cell, anode electrode layers 11₁, 11₂, 11₃, 11₄ and cathode electrode layers 16₁, 16₂, 16₃, 16₄ are respectively disposed so as to sandwiching organic layers 14₁, 14₂, 14₃, 14₄. The anode electrode layers 11₁, 11₂, 11₃, 11₄ are respectively connected to the anode electrode A1, A2, A3, A4, and the cathode electrode layers 16₁, 16₂, 16₃, 16₄ are respectively connected to the cathode electrodes K1, K2, K3, K4. Furthermore, the anode terminal A is connected to the anode electrode A1, the cathode electrode K1 is connected to the anode electrode A2, the cathode electrode K2 is connected to the anode electrode A3, the cathode electrode K3 is connected to the anode electrode A4, and the cathode electrode K4 is connected to the cathode terminal K.

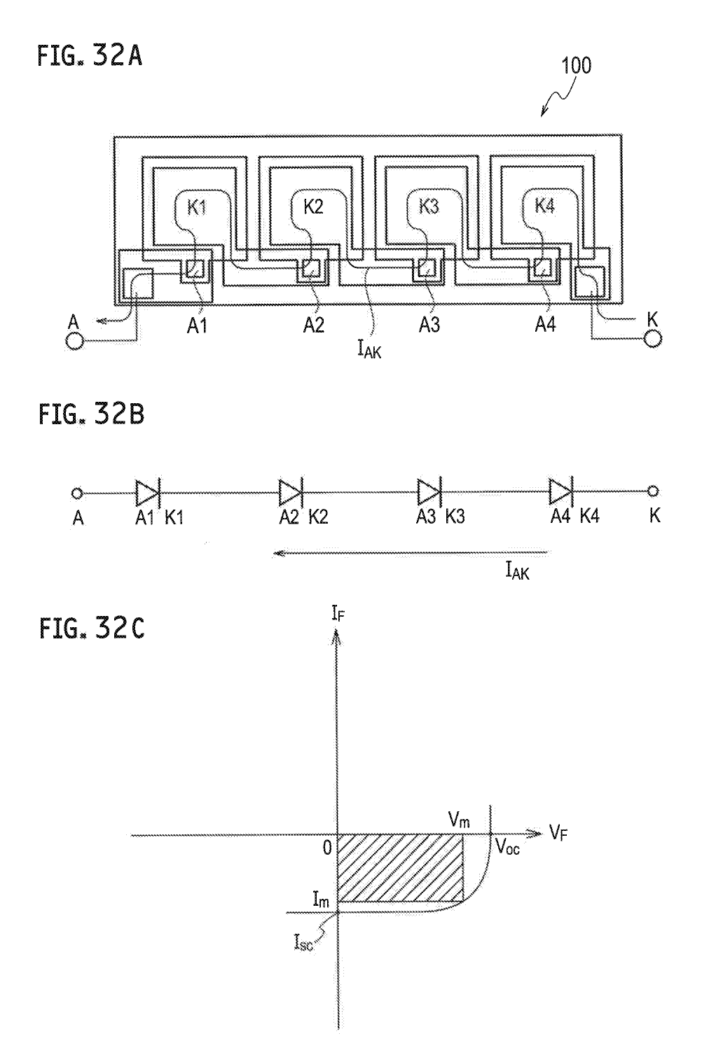

Moreover, FIG. 32A schematically shows a conduction path of a photo-electric current I_{AK}, in the organic thin film photovoltaic device module of a 4-cells serial structure shown in FIG. 31A. FIG. 32B shows a conducting direction of the photo-electric current I_{AK} in equivalent circuit representation, and FIG. 32C shows a schematic diagram of current-voltage characteristics.

The conduction path of the photo-electric current I_{AK} is expressed as follows: the cathode terminal K→the cathode electrode K4; the anode electrode A4→the cathode electrode K3; the anode electrode A3→the cathode electrode K2; the anode electrode A2→the cathode electrode K1; and the anode electrode A1→the anode terminal A, as schematically shown in FIG. 32A. Moreover, in the organic thin film photovoltaic device module having 4-cells serial structure, V_{oc} denotes an open voltage, I_{sc} denotes a short-circuit current, and V_{oc} and Iₘ respectively denotes voltage and electric current when giving the maximum electric output power.

### (Producing Steps of Organic Thin Film Photovoltaic Device)

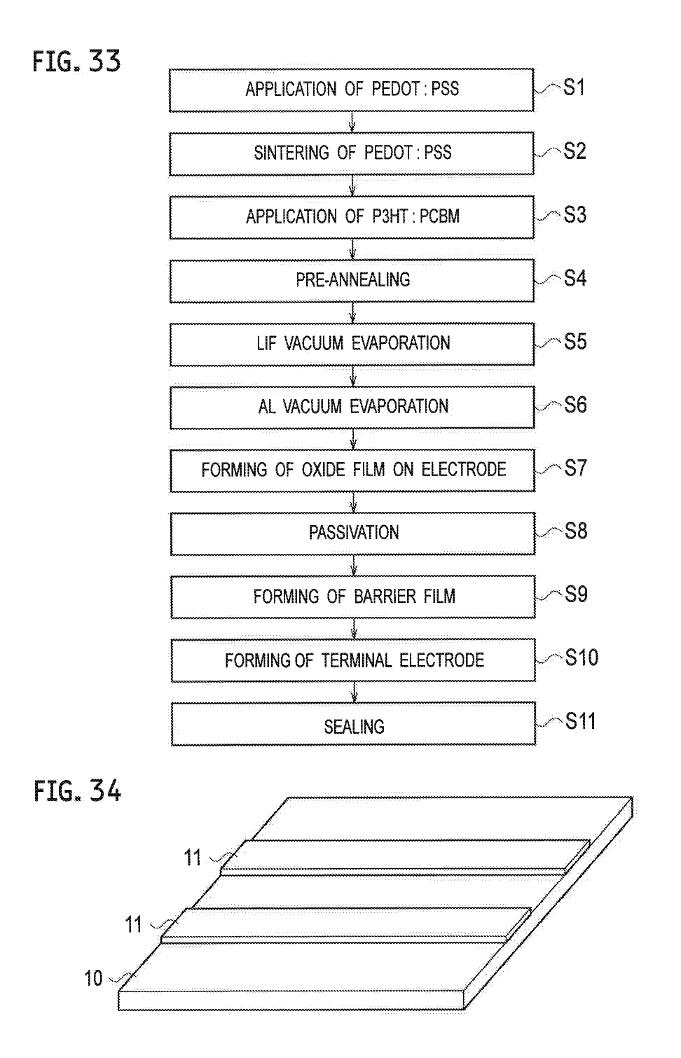

In accordance with the flow chart shown in FIG. 33, there will now be explained producing steps of the organic thin film photovoltaic device 100 according to the embodiment.

(a) In Step S1, PEDOT:PSS is coated on the ITO substrate 10. For example, PEDOT:PSS aqueous solution is filtered with a 0.45-μm PTFE membrane filter to remove undissolved matters and impurities, and then the PEDOT:PSS aqueous solution is coated on the ITO substrate 10 with spin coating (for example, 4000 rpm for 30 sec).
(b) In Step S2, the PEDOT:PSS is sintered. More specifically, heat-treatment is performed at 120 degrees C. for 10 minutes for the purpose of water removal, after the film formation. In addition, it is effective to cover a petri dish previously heated by a hot plate so that the heat may be transferred to whole of the substrate 10. The hole transport layer 12 is formed on the transparent electrode layer 11 on the ITO substrate 10 by the above-mentioned processes.
(c) In Step S3, P3HT:PCBM is coated on the substrate 10. Specifically, P3HT 16 mg and PCBM 16 mg are dissolved in dichlorobenzene (o-dichlorobenzene), for example. The solution is subjected to ultrasonic treatment for 1 minute at 50 degrees C., after agitating at 50 degrees C. under nitrogen atmosphere for a night. Spin coating of the solution is performed on the ITO substrate 10 subjected to washing treatment in a glove box replaced with nitrogen (<1 ppm O₂, H₂O). A rotational frequency of the spin coating is 2000 rpm per 1 sec after 550 rpm per 60 sec.
(d) In Step S4, pre-annealing is performed. More specifically, heating processing is performed for 10 minutes at 120 degrees C. after the coating of Step S3. In addition, it is effective to cover a petri dish previously heated by a hot plate so that the heat may be transferred to whole of the substrate 10. By the above-mentioned processes, the bulk heterojunction organic active layer 14A is formed on the hole transport layer 12, and thereby the organic layer 14 (12+14A) is formed.
(e) In Step S5, LiF vacuum evaporation is performed. Specifically, as for LiF (purity: 99.98%), vacuum thermal evaporation is performed with the vacuum degree: 1.1×10⁻⁶ torr and the vacuum evaporation rate: 0.1 angstrom/sec. The LiF used for an electronic injection layer with respect to the bulk heterojunction organic active layer 14A.
(f) In Step S6, Al vacuum evaporation is performed, thereby forming the second electrode layer 16 on the organic layer 14. Specifically, as for Al (purity: 99.999&), vacuum thermal evaporation is performed with the vacuum degree: 1.1×10⁻⁶ torr and the vacuum evaporation rate: more than 2 angstroms/sec.
(g) In Step S7, an oxide film is formed on the second electrode layer 16. Specifically, the surface of the second electrode layer 16 is oxidized with oxygen plasma by using a high-density plasma etching apparatus, thereby forming the oxide film (passive state film).
(h) In Step S8, passivation sealing is performed. Specifically, in the passivation processing, the passivation layer 26 is formed on the entire device.
(i) In Step S9, the barrier film 36 is bonded onto the passivation layer 26 via the photo-curing resin layer 34. The photo-curing (UV-curing) resin layer 34 is coated thereon by a spin coat method etc., the barrier film 36 is bonded, and then is cured by UV irradiation.
(j) In Step S10, the extraction terminal electrode 2 (+) is formed. A carbon paste, an Ag paste, etc. are used for a bonding junction portion of the extraction terminal electrode 2 (+).
(k) In Step S11, sealing is performed. Specifically, a peripheral portion thereof is protected by resin layers, e.g. a UV curing resin, etc. from infiltration of moisture, oxygen, etc.

### (Mass Production Process)

As shown in FIGS. 34-38, the organic thin film photovoltaic device according to the embodiment can also be fabricated with a mass production process by disposing a plurality of cells in a matrix shape.

Hereinafter, the mass production process will now be explained with reference to FIGS. 34-38.

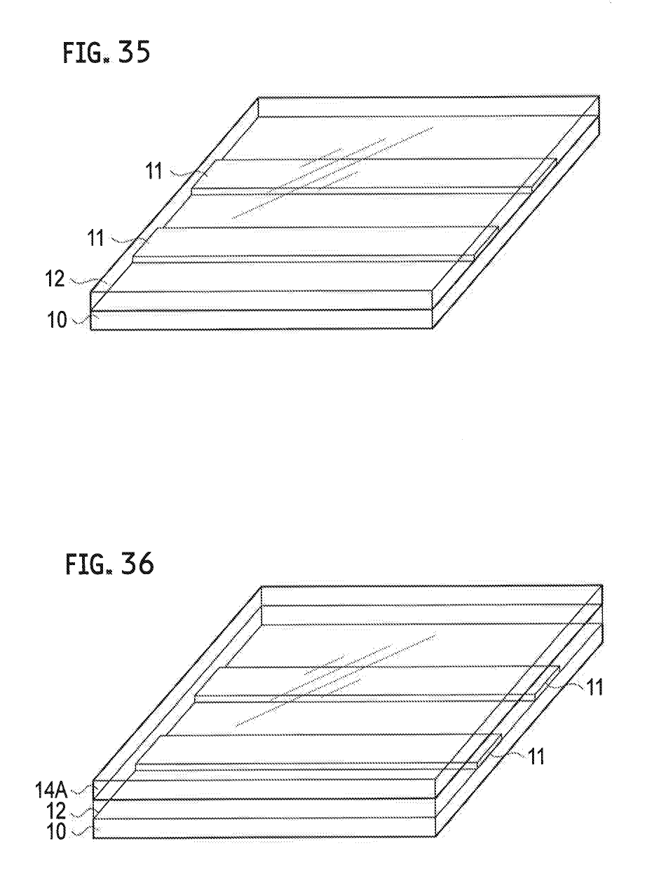

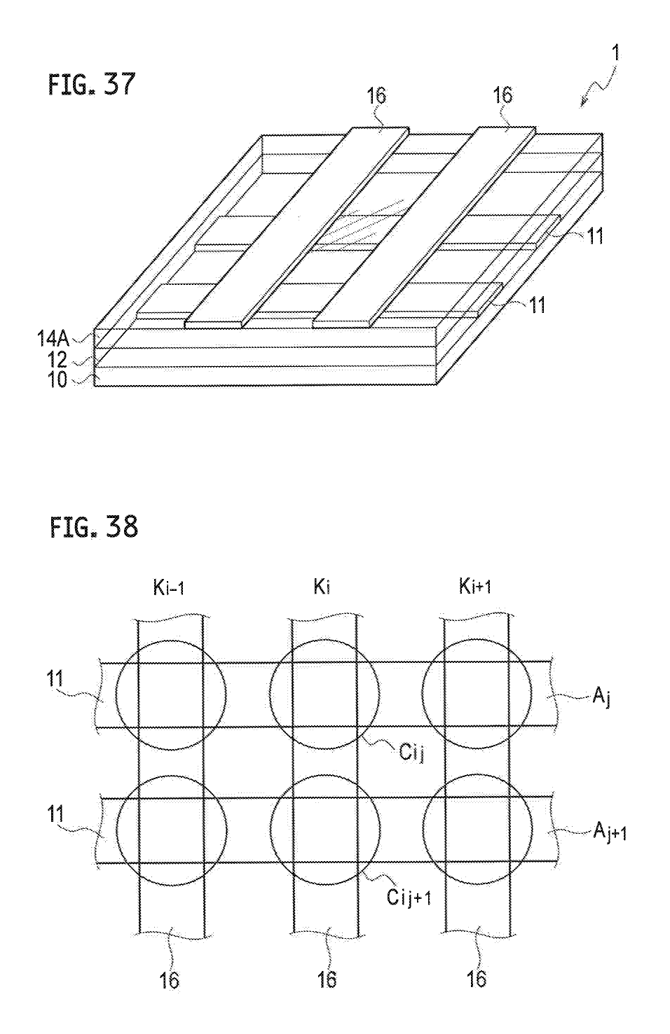

(a) Firstly, a glass substrate 10 washed by pure water, acetone and ethanol are inserted into an ICP etcher, and adherents on the surface of the glass substrate are removed by O₂ plasma (Glass Substrate Surface Treatment). In addition, an antireflection process may be applied on the surface of the glass substrate 10 in order to efficiently guide light to the organic active layer.
(b) Next, as shown in FIG. 34, the optically transmissive electrode layer 11 composed including, for example, ITO is formed on the substrate 10. In an example shown in FIG. 34, a plurality of the transparent electrode layers 11 are formed in a stripe pattern so as to sandwich a gap. A laser patterning technology etc. are also applicable to the forming of the gap.
(c) Next, as shown in FIG. 35, the hole transport layer 12 is formed on the substrate 10 and the transparent electrode layer 11. Spin coating technology, spray technology, screen printing technology, etc. can be applied to the formation of the hole transport layer 12. In this case, in the process for forming the hole transport layer 12, the film formation is performed, for example, by spin coating of PEDOT:PSS, and annealing is applied thereto for approximately 10 minutes at 120 degrees C. for the purpose of water removal.
(d) Next, as shown in FIG. 36, the bulk heterojunction organic active layer 14A is formed on the hole transport layer 12. In the formation process of the bulk heterojunction organic active layer 14A, film formation is performed with spin coating of P3HT:PCBM, for example. The thickness of the bulk heterojunction organic active layer 14A is approximately 100 nm to approximately 200 nm, for example.
(e) Next, as shown in FIG. 37, on the bulk heterojunction organic active layer 14A, the cathode electrode layers 16 in two-stripes pattern are formed so as to be orthogonal to the transparent electrode layer 11.

The cathode electrode layer 16 is formed by depositing Al, W, Mo, Mn, Mg, etc., for example, by vacuum thermal vapor deposition. Screen printing technology instead of the vacuum thermal vapor deposition may be applied to the formation of the cathode electrode layer 16.

(f) Next, an oxide film (passive state film) not shown is formed on the surface of the cathode electrode layer 16. The passive state film can be formed by exposing the cathode electrode layer 16 to oxygen plasma. The oxide film with the oxygen plasma can be formed using a plasma etching apparatus, for example.
(g) Next, although illustration is omitted, the barrier film 36 is formed via the photo-curing resin layer 34 on the passivation layer 26 and a passivation layer 26, on the entire device.

According to the above-mentioned processes, the organic thin film photovoltaic device 100 according to the embodiment can be mass-produced.

In the organic thin film photovoltaic device 100 according to the embodiment, an example of a schematic planar pattern configuration to dispose a plurality of cells Cᵢⱼ in a matrix shape is expressed as shown in FIG. 38. The cells . . . Cᵢⱼ, . . . are disposed at intersections between the anode electrodes . . . , Aⱼ, Aⱼ₊₁, . . . formed of the anode electrode layer 11, and the cathode electrodes . . . , Kᵢ₋₁, Kᵢ, Kᵢ₊₁, . . . formed of the cathode electrode layer 16 to intersect perpendicularly with the anode electrodes . . . , Aⱼ, Aⱼ₊₁, . . . . The characteristics of each cell . . . Cᵢⱼ, . . . disposed on the intersections can also be measured independently by selecting the anode electrodes . . . , Aⱼ, Aⱼ₊₁, . . . and the cathode electrodes . . . , Kᵢ₋₁, Kᵢ, Kᵢ₊₁, . . . .

### (Spin Coat Method)

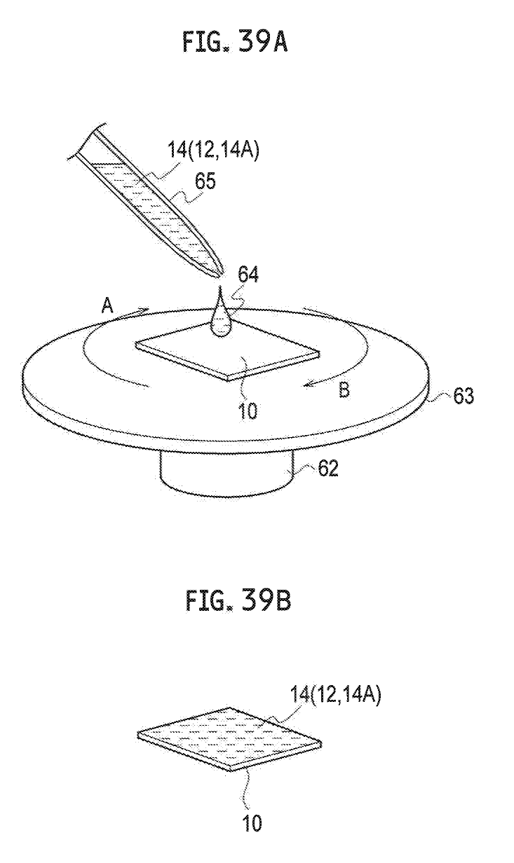

FIG. 39A shows an outline showing a spin coat method at the time of forming the hole transport layer 12 and the organic layer 14 (12, 14A), in the fabrication method of the organic thin film photovoltaic device 100 according to the embodiment. FIG. 39B shows a schematic bird's-eye view configuration showing an example of the formed hole transport layer 12 and the formed organic layer (12, 14A).

For example, if a relative small-area element is created, a spin coat method as shown in FIG. 39A can be applied, in the organic thin film photovoltaic device 100 according to the embodiment.

More specifically, a spin coater including a high-speed rotating spindle 62 connected to driving sources, e.g. a motor, and a table fixed to the spindle 62, wherein the substrate 10 is mounted on the table is used therefor, as shown in FIG. 39A.

Then, the driving source, e.g. a motor, is worked after the substrate 10 is mounted on the table 63, and then the table 63 is rotated at a high speed, e.g., 2000-4000 rpm, in arrows A, B direction. Subsequently, a droplet 64 of a solution for forming the hole transport layer 12 and the bulk heterojunction organic active layer 14A is dropped thereon using a syringe 65. Thereby, the hole transport layer 12 and the bulk heterojunction organic active layer 14A having uniform thickness (refer to FIG. 39B) can be formed with the droplet 64 on the substrate 10 in accordance with centrifugal force.

### (Electronic Apparatus)

The embodiment provides the organic thin film photovoltaic device, of which the fabrication process is simplified and durability is excellent, by bonding the barrier film excellent in the mechanical strength and the barrier property to the single-layered protection film with the UV curing resin. Accordingly, it becomes easy to mount mobile terminal equipment etc. in the electronic apparatus. Since external views are important for electronic apparatuses represented by in particular smartphones and tablet-type devices, the cell of the organic thin film photovoltaic device can be mounted in a bezel (peripheral portion of a display unit) and a back surface of a display panel.

As mentioned above, the embodiment can provide: the organic thin film photovoltaic device, of which the fabrication process is simplified and durability is excellent, by bonding the barrier film excellent in the mechanical strength and the barrier property to the single-layered protection film with the UV curing resin; the fabrication method of such an organic thin film photovoltaic device; and the electronic apparatus in which such an organic thin film photovoltaic device is mounted.

### Other Embodiments

As explained above, the embodiment has been described, as a disclosure including associated description and drawings to be construed as illustrative, not restrictive. This disclosure makes clear a variety of alternative embodiment, working examples, and operational techniques for those skilled in the art.

Such being the case, the embodiment described herein covers a variety of embodiments, whether described or not.

### INDUSTRIAL APPLICABILITY

The organic thin film photovoltaic device of the embodiment can be applied to wide fields, e.g. photovoltaic power generation panels, chargers for mobile terminals, etc.

What is claimed is:

1. An organic thin film photovoltaic device comprising:
a substrate;
a transparent electrode layer disposed on the substrate;
an organic layer disposed on the transparent electrode layer;
a metal electrode layer disposed on the organic layer;
a passivation layer disposed on the metal electrode layer;
a photo-curing resin layer disposed on the passivation layer; and
a barrier film disposed on the photo-curing resin layer.

2. The organic thin film photovoltaic device according to claim 1, wherein
the barrier film comprises a sheet glass.

3. The organic thin film photovoltaic device according to claim 1, wherein
the barrier film comprises a plastic film.

4. The organic thin film photovoltaic device according to claim 1, further comprising:
an extraction terminal electrode disposed in a perpendicular-to-plane direction with respect to the substrate, the extraction terminal electrode connected to the first electrode layer, passing through the barrier film, the photo-curing resin layer, and the passivation layer.

5. The organic thin film photovoltaic device according to claim 1, further comprising:
an extraction terminal electrode disposed on an edge face of the substrate, the extraction terminal electrode connected to the first electrode layer at the edge face.

6. The organic thin film photovoltaic device according to claim 1, wherein
the passivation layer comprises an SiN film or SiON film.

7. An organic thin film photovoltaic device comprising an organic thin film photovoltaic device cell, the organic thin film photovoltaic device cell comprising:
a substrate;
a first electrode layer disposed on the substrate;
an organic layer disposed on the first electrode layer;
a second electrode layer disposed on the organic layer;
a passivation layer disposed on the second electrode layer;
a photo-curing resin layer disposed on the passivation layer; and
a barrier film disposed on the photo-curing resin layer, wherein
a plurality of the organic thin film photovoltaic device cells are connected to one another in series.

8. The organic thin film photovoltaic device according to claim 1, wherein
the organic layer comprises:
a hole transport layer; and
a bulk heterojunction organic active layer disposed on the hole transport layer.

9. The organic thin film photovoltaic device according to claim 1, wherein
the metal electrode layer comprises: a passive state film formed on a surface of the metal electrode layer.

10. An electronic apparatus comprising an organic thin film photovoltaic device, the organic thin film photovoltaic device comprising:
a substrate;
a transparent electrode layer disposed on the substrate;
an organic layer disposed on the transparent electrode layer;
a metal electrode layer disposed on the organic layer;
a passivation layer disposed on the metal electrode layer;
a photo-curing resin layer disposed on the passivation layer; and
a barrier film disposed on the photo-curing resin layer.
